(19) United States
(12) Patent Application Publication
(10) Pub. No.: US 2025/0014965 A1
(43) Pub. Date: Jan. 9, 2025

(54) THERMAL INTERFACE MATERIAL

(71) Applicant: Henkel AG & Co. KGaA, Duesseldorf (DE)

(72) Inventors: Yong Joon Lee, Burlington, MA (US); William J. Scimeca, Boston, MA (US); Nicolo Brambilla, Boston, MA (US); Albrecht Becker, Boxford, MA (US)

(21) Appl. No.: 18/890,855

(22) Filed: Sep. 20, 2024

Related U.S. Application Data
(63) Continuation of application No. PCT/US2023/015909, filed on Mar. 22, 2023.
(60) Provisional application No. 63/322,374, filed on Mar. 22, 2022.

(51) Int. Cl. H01L 23/373; C08K 3/04; C08K 3/38; C09J 113/00; H01L 23/00

(52) U.S. Cl. CPC H01L 23/3737; C09J 113/00; H01L 24/29; H01L 24/32; C08K 3/042; C08K 3/38; C08K 2003/385; H01L 2224/2929; H01L 2224/293; H01L 2224/29393; H01L 2224/32245

(57) ABSTRACT

A thermal interface material that conducts heat is disclosed. The thermal interface includes a bulk layer and at least one adhesive layer. The bulk layer includes a first acrylic rubber, plasticizer particles, and first filler particles, and the first filler particles are substantially aligned in a first direction. The first adhesive layer is disposed on a first side of the bulk material. The first adhesive layer has a greater tackiness than the bulk material. The first adhesive layer comprises a second acrylic rubber. The first direction is substantially perpendicular to a first surface of the first side on which the first adhesive layer is disposed.

### BACKGROUND

The invention disclosed herein relates to thermal interface materials and, in particular, to composite materials for providing efficient transfer of heat away from certain areas such as electronic components or other surfaces that are subject to heat.

### BRIEF DESCRIPTION OF THE DRAWINGS

The following is a brief description of the drawings wherein like elements are numbered alike and which are presented for the purposes of illustrating the exemplary embodiments disclosed herein and not for the purposes of limiting the same.

FIG. 1 is a schematic diagram depicting aspects of a heat generating component, a heat sink and use of thermal interface materials.

FIG. 2A is a diagram of a thermal interface material according to various embodiments.

FIG. 2B is a diagram of a thermal interface material according to various embodiments.

FIG. 3A is a diagram depicting aspects of a thermal interface material according to various embodiments.

FIG. 3B is a diagram depicting aspects of a thermal interface material according to various embodiments.

FIG. 3C is a diagram depicting aspects of a thermal interface material according to various embodiments.

FIG. 4 is a schematic diagram of a thermal interface material pad according to various embodiments.

FIG. 5 is a plot of thermal impedance vs. pressure for six samples of thermal interface material pads. The upper three traces show results for samples without surface treatment. The lower three traces show results for samples with surface treatment of the type illustrated in FIG. 4.

FIG. 6 is a schematic diagram of a thermal interface material pad according to various embodiments.

FIG. 7A is an illustration of the initial steps in a method of fabrication of a thermal interface pad according to various embodiments.

FIG. 7B is an illustration of the final steps in a method of fabrication of a thermal interface pad according to various embodiments.

FIG. 8A is an illustration of the initial steps in a method of fabrication of a thermal interface pad according to various embodiments.

FIG. 8B is an illustration of the final steps in a method of fabrication of a thermal interface pad according to various embodiments.

FIG. 9 is a depiction of a block of stacked thermal interface material layers, each layer made up of a dispersion of dimensionally oriented materials according to various embodiments.

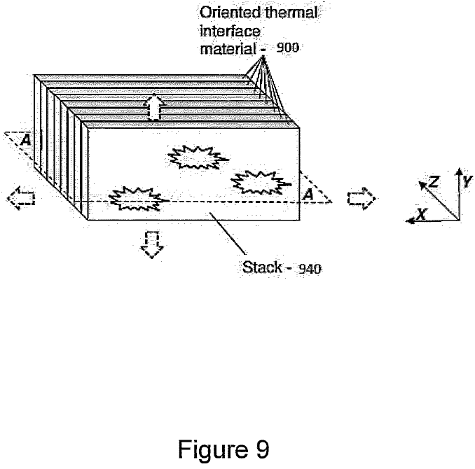

FIG. 10 is a depiction of a thermal interface material pad containing dimensionally oriented material, which could be cut from a block like that shown in FIG. 9.

FIG. 11 is a graph depicting thermal performance for the oriented pad disclosed herein in comparison to competitive products.

FIG. 12 is graph showing comparative performance of embodiments of thermal interface materials.

FIG. 13 is graph showing comparative performance of embodiments of thermal interface materials.

FIG. 14 is graph showing comparative performance of embodiments of thermal interface materials.

FIG. 15 is a chart showing characteristics of thermal interface materials according to various embodiments.

FIG. 16 is a chart showing characteristics of thermal interface materials according to various embodiments.

### DETAILED DESCRIPTION

A more complete understanding of the components, processes, and apparatuses disclosed herein can be obtained by reference to the accompanying drawings. These figures (also referred to herein as “FIG.”) are merely schematic representations based on convenience and the ease of demonstrating the present disclosure, and are, therefore, not intended to indicate relative size and dimensions of the devices or components thereof and/or to define or limit the scope of the exemplary embodiments. Although specific terms are used in the following description for the sake of clarity, these terms are intended to refer only to the particular structure of the embodiments selected for illustration in the drawings and are not intended to define or limit the scope of the disclosure. In the drawings and the following description below, it is to be understood that like numeric designations refer to components of like function.

The following example are merely illustrative of the thermal interface material disclosed herein and are not intended to limit the scope hereof.

Prior to introducing the thermal interface materials (TIM), some terminology is provided to establish context for the teachings herein.

Generally, the term “self-healing” refers to materials that have the built-in ability to automatically repair damage to themselves without any external diagnosis of the problem or human intervention. Typically, conventional materials will degrade over time due to fatigue, environmental conditions, or damage incurred during operation. Cracks and other types of damage on a microscopic level have been shown to change thermal, electrical, and acoustical properties of the conventional materials, and the propagation of cracks can lead to eventual failure of the conventional material. In general, cracks are hard to detect at an early stage, and manual intervention is required for periodic inspections and repairs. In contrast, self-healing materials counter degradation through the initiation of a repair mechanism that responds to the micro-damage.

Generally, “thermal conductivity” (often denoted as k, λ, or κ) refers to the ability of a material to conduct heat. Thermal conductivity is evaluated primarily in terms of Fourier's Law for heat conduction. In general, thermal conductivity is a tensor property, expressing the anisotropy of the property.

Heat transfer occurs at a lower rate in materials of low thermal conductivity than in materials of high thermal conductivity. Correspondingly, materials of high thermal conductivity are used in heat sink applications and materials of low thermal conductivity are used as thermal insulation. The thermal conductivity of a material may depend on temperature. The reciprocal of thermal conductivity is called “thermal resistivity.”

Thermal conductivity may be expressed as provided in Eq. (1):

$$\vec{\text{?}} = ( - {k}_{\vec{∇}} T ) \qquad Eq . ( 1 )$$

$$\text{?} \text{indicates text missing or illegible when filed}$$

where

$$\vec{\text{?}}$$

$$\text{?} \text{indicates text missing or illegible when filed}$$

represents the neat flux, −k represents the thermal conductivity, and

$$( \vec{∇} T )$$

represents the temperature gradient.

Generally, as discussed herein, the term “thermal impedance” refers to the sum of thermal resistance and all contact resistances for a material. When thermal impedance is lower for a material, the material is a better thermal conductor in that application. Thus, factors such as surface roughness, surface flatness, clamping pressure, presence of adhesive, non-homogeneous, and material thickness are factors that influence thermal impedance for a material. Generally, thermal impedance is a useful metric for assessing thermal performance, as thermal impedance accounts for more variables specific to the application.

As used herein, an “isotropically oriented” set of elements is to be understood to be randomly or substantially randomly arranged such that the elements are not preferentially aligned or are not substantially preferentially aligned along a particular direction in space.

As used herein, an “anisotropically oriented” set of elements is to be understood to be arranged such that the elements are substantially preferentially aligned along a particular direction in space.

Various embodiments disclose a thermal interface material (TIM). The TIM includes a bulk layer and at least one adhesive layer. The bulk layer includes a first acrylic rubber, plasticizer particles, and first filler particles, and the first filler particles are substantially aligned in a first direction. The first adhesive layer is disposed on a first side of the bulk material. The first adhesive layer has a greater tackiness than the bulk material. The first adhesive layer comprises a second acrylic rubber. The first direction is substantially perpendicular to a first surface of the first side on which the first adhesive layer is disposed.

According to various embodiments, the plasticizer particles (e.g., the plasticizer particles comprised in the bulk layer) have a specific gravity (@25/25) of about 1.062 as measured in accordance with ASTM D4052. In some embodiments, the plasticizer particles have a specific gravity (@25/25) of between 1.050 and 1.070 as measured in accordance with ASTM D4052. According to various embodiments, the plasticizer particles have a viscosity (@25° C.) of about 930 as measured in accordance with ASTM D4455. In some embodiments, the plasticizer particles have a viscosity (@25° C.) of between 900 and 1000 as measured in accordance with ASTM D4455.

According to various embodiments, the plasticizer particles (e.g., the plasticizer particles comprised in the bulk layer) have a viscosity (@25° C.) of about 850 as measured in accordance with ASTM D4455. In some embodiments, the plasticizer particles have a viscosity (@25° C.) of between 850 and 1000 as measured in accordance with ASTM D4455.

In some embodiments, the plasticizer particles (e.g., the plasticizer particles comprised in the bulk layer) have a viscosity (@25° C.) of between 800 and 1000 as measured in accordance with ASTM D4455.

In some embodiments, the TIM has a tensile strength in a direction parallel to a thickness of the TIM that is different from a tensile strength in a direction of the width or length of the TIM (e.g., a direction perpendicular to the thickness of the TIM). In some embodiments, the TIM has a tensile strength in a direction parallel to the width of the TIM that is different from a tensile strength in a direction parallel to a length of the TIM. For example, a first tensile strength of the TIM along the first direction is different from a second tensile strength of the TIM along a direction that is perpendicular to the first direction. In some embodiments, a tensile strength of the TIM along the first direction is less than a tensile strength of the TIM along a direction that is perpendicular to the first direction. For example, a first tensile strength of the thermal interface material along the first direction is different from a second tensile strength of the thermal interface material along a direction that is perpendicular to the first direction. A ratio of the second tensile strength to the first tensile strength may be at least 1.5 to 1. A ratio of the second tensile strength to the first tensile strength may be at least 2 to 1. A ratio of the second tensile strength to the first tensile strength may be at least 2.5 to 1. A ratio of the second tensile strength to the first tensile strength may be at least 3 to 1.

In some embodiments, a TIM includes a bulk layer and at least one adhesive layer. The bulk layer includes a first acrylic rubber, plasticizer particles, and first filler particles, and the first filler particles are substantially aligned in a first direction. In some embodiments, the first filler particles comprise a first subset of first filler particles and a second subset of the first filler particles. The first subset of first filler particles and the second subset of first filler particles are different at least with respect to one attribute. As an example, an average size of the first subset of first filler particles is larger than an average size of the second subset of the first filler particles. As another example, a thermal conductivity of the first subset of first filler particles if more uniform than a thermal conductivity of the second subset of first filler particles.

In some embodiments, a TIM includes a bulk layer and at least one adhesive layer. The bulk layer includes a first acrylic rubber, plasticizer particles, and first filler particles, and the first filler particles are substantially aligned in a first direction. The first direction can correspond to a direction in which heat is desired to be conducted, or a direction in which heat is maximally conducted in the TIM. For example, the first direction can correspond to a thickness of the TIM. In some embodiments, the bulk layer can comprise a set of slices or layers that are stacked or compressed together. The direction in which the slices or layers are stacked/compressed can be substantially parallel to an orthogonal vector with respect to a surface of the corresponding slice or layer (which may be referred to herein as the first direction). In some embodiments, the first direction substantially corresponds to an axis along which the various slices or layers interface with one another. Each of the slices/layers in the set of slices or layers are substantially the same (e.g., manufactured according to a same process. For example, the set of slices or layers can respectively comprise the first acrylic rubber, the plasticizer particles, and first filler particles. As an example, the alignment of the first filler particles in the first direction comprises more than 50% of the first filler particles being aligned in the first direction.

In some embodiments, the substantial alignment of the first filler particles in the first direction comprises at least 75% of the first filler particles being aligned in the first direction, and the first filler particles being aligned in the first direction comprises a longest side of the first filler particles being parallel to the first direction. In some embodiments, the substantial alignment of the first filler particles in the first direction comprises at least 85% of the first filler particles being aligned in the first direction, and the first filler particles being aligned in the first direction comprises a longest side of the first filler particles being parallel to the first direction. In some embodiments, the substantial alignment of the first filler particles in the first direction comprises at least 90% of the first filler particles being aligned in the first direction the first filler particles being aligned in the first direction comprises a longest side of the first filler particles being parallel to the first direction.

In some embodiments, the substantial alignment of the first filler particles in the first direction comprises at least 75% of the first filler particles being aligned in the first direction, and the first filler particles being aligned in the first direction comprises a longest side of the first filler particles being within 5 degrees of the first direction. In some embodiments, the substantial alignment of the first filler particles in the first direction comprises at least 85% of the first filler particles being aligned in the first direction, and the first filler particles being aligned in the first direction comprises a longest side of the first filler particles being within 5 degrees of the first direction. In some embodiments, the substantial alignment of the first filler particles in the first direction comprises at least 90% of the first filler particles being aligned in the first direction, and the first filler particles being aligned in the first direction comprises a longest side of the first filler particles being within 5 degrees of the first direction. In some embodiments, the substantially alignment of the first filler particles in the first direction comprises at least 90% of the first filler particles being aligned in the first direction, and the first filler particles being aligned in the first direction comprises a longest side of the first filler particles being within 5 degrees of the first direction.

The bulk layer of the TIM comprises the first filler particles. In some embodiments, the bulk layer is 80% first filler particles by weight. The first filler particles can comprise ceramic particles. The first filler particles may be planar.

According to various embodiments, a TIM is disclosed, and the TIM comprises a bulk layer and a first adhesive layer applied to a first side of the bulk layer, and a second adhesive layer applied to a second side of the bulk layer. The second side of the bulk layer can be an opposing side with respect to the first side of the bulk layer.

Various embodiments disclose a thermal interface material (TIM). The TIM includes a bulk layer and at least one adhesive layer. The bulk layer includes a first acrylic rubber, plasticizer particles, and first filler particles, and the first filler particles are substantially aligned in a first direction. The first adhesive layer is disposed on a first side of the bulk material. The first adhesive layer has a greater tackiness than the bulk material. The first adhesive layer comprises a second acrylic rubber. The first direction is substantially perpendicular to a first surface of the first side on which the first adhesive layer is disposed.

In some embodiments, the TIM has a tensile strength in a direction parallel to a thickness of the TIM that is different from a tensile strength in a direction of the width or length of the TIM (e.g., a direction perpendicular to the thickness of the TIM). In some embodiments, the TIM has a tensile strength in a direction parallel to the width of the TIM that is different from a tensile strength in a direction parallel to a length of the TIM. For example, a first tensile strength of the TIM along the first direction is different from a second tensile strength of the TIM along a direction that is perpendicular to the first direction. In some embodiments, a tensile strength of the TIM along the first direction is less than a tensile strength of the TIM along a direction that is perpendicular to the first direction. For example, a first tensile strength of the thermal interface material along the first direction is different from a second tensile strength of the thermal interface material along a direction that is perpendicular to the first direction. A ratio of the second tensile strength to the first tensile strength may be at least 1.5 to 1. A ratio of the second tensile strength to the first tensile strength may be at least 2 to 1. A ratio of the second tensile strength to the first tensile strength may be at least 2.5 to 1. A ratio of the second tensile strength to the first tensile strength may be at least 3 to 1.

In some embodiments, a TIM includes a bulk layer and at least one adhesive layer. The bulk layer includes a first acrylic rubber, plasticizer particles, and first filler particles, and the first filler particles are substantially aligned in a first direction. In some embodiments, the first filler particles comprise a first subset of first filler particles and a second subset of the first filler particles. The first subset of first filler particles and the second subset of first filler particles are different at least with respect to one attribute. As an example, an average size of the first subset of first filler particles is larger than an average size of the second subset of the first filler particles. As another example, a thermal conductivity of the first subset of first filler particles if more uniform than a thermal conductivity of the second subset of first filler particles.

In some embodiments, a TIM includes a bulk layer and at least one adhesive layer. The bulk layer includes a first acrylic rubber, plasticizer particles, and first filler particles, and the first filler particles are substantially aligned in a first direction. The first direction can correspond to a direction in which heat is desired to be conducted, or a direction in which heat is maximally conducted in the TIM. For example, the first direction can correspond to a thickness of the TIM. In some embodiments, the bulk layer can comprise a set of slices or layers that are stacked or compressed together. The direction in which the slices or layers are stacked/compressed can be substantially parallel to an orthogonal vector with respect to a surface of the corresponding slice or layer (which may be referred to herein as the first direction). In some embodiments, the first direction substantially corresponds to an axis along which the various slices or layers interface with one another. Each of the slices/layers in the set of slices or layers are substantially the same (e.g., manufactured according to a same process. For example, the set of slices or layers can respectively comprise the first acrylic rubber, the plasticizer particles, and first filler particles. As an example, the alignment of the first filler particles in the first direction comprises more than 50% of the first filler particles being aligned in the first direction.

In some embodiments, the substantial alignment of the first filler particles in the first direction comprises at least 75% of the first filler particles being aligned in the first direction, and the first filler particles being aligned in the first direction comprises a longest side of the first filler particles being parallel to the first direction. In some embodiments, the substantial alignment of the first filler particles in the first direction comprises at least 85% of the first filler particles being aligned in the first direction, and the first filler particles being aligned in the first direction comprises a longest side of the first filler particles being parallel to the first direction. In some embodiments, the substantial alignment of the first filler particles in the first direction comprises at least 90% of the first filler particles being aligned in the first direction the first filler particles being aligned in the first direction comprises a longest side of the first filler particles being parallel to the first direction.

In some embodiments, the substantial alignment of the first filler particles in the first direction comprises at least 75% of the first filler particles being aligned in the first direction, and the first filler particles being aligned in the first direction comprises a longest side of the first filler particles being within 5 degrees of the first direction. In some embodiments, the substantial alignment of the first filler particles in the first direction comprises at least 85% of the first filler particles being aligned in the first direction, and the first filler particles being aligned in the first direction comprises a longest side of the first filler particles being within 5 degrees of the first direction. In some embodiments, the substantial alignment of the first filler particles in the first direction comprises at least 90% of the first filler particles being aligned in the first direction, and the first filler particles being aligned in the first direction comprises a longest side of the first filler particles being within 5 degrees of the first direction. In some embodiments, the substantially alignment of the first filler particles in the first direction comprises at least 90% of the first filler particles being aligned in the first direction, and the first filler particles being aligned in the first direction comprises a longest side of the first filler particles being within 5 degrees of the first direction.

The bulk layer of the TIM comprises the first filler particles. In some embodiments, the bulk layer is 80% first filler particles by weight. The first filler particles can comprise ceramic particles. The first filler particles may be planar.

According to various embodiments, a TIM is disclosed, and the TIM comprises a bulk layer and a first adhesive layer applied to a first side of the bulk layer, and a second adhesive layer applied to a second side of the bulk layer. The second side of the bulk layer can be an opposing side with respect to the first side of the bulk layer.

Various embodiments include a power supply comprising a TIM as disclosed herein. The TIM may enhance the thermal conductivity between two components. For example, the TIM provides a conduction of heat generated from one or more other components (e.g., an integrated circuit, etc.). Because power supplies generate relatively large amounts of heat, the TIM is used to conduct heat from the heat source (or components in proximity to the heat source that themselves become increasingly hot) to a heat dissipating device, such as a heat sink.

Various embodiments include a control system for controlling one or more motors. The control system comprises a TIM as disclosed herein. The TIM may enhance the thermal conductivity between two components. For example, the TIM provides a conduction of heat generated from one or more other components (e.g., an integrated circuit, etc.). Because motor control systems generate relatively large amounts of heat, the TIM is used to conduct heat from the heat source (or components in proximity to the heat source that themselves become increasingly hot) to a heat dissipating device, such as a heat sink.

Various embodiments include a semiconductor circuit. The semiconductor circuits may comprise integrated circuits used in connection with power generation or otherwise used in connection with controlling power systems. The semiconductor circuits comprise a TIM as disclosed herein. The TIM may enhance the thermal conductivity between two components. For example, the TIM provides a conduction of heat generated from one or more other components (e.g., an integrated circuit, etc.). Because power semiconductors generate relatively large amounts of heat, the TIM is used to conduct heat from the heat source (or components in proximity to the heat source that themselves become increasingly hot) to a heat dissipating device, such as a heat sink.

Various embodiments include an optical display. The optical display may comprise an LED light source, a laser light source, an incandescent bulb, etc. Various other light sources can be implemented. The control system comprises a TIM as disclosed herein. The TIM may enhance the thermal conductivity between two components. For example, the TIM provides a conduction of heat generated from one or more other components (e.g., an integrated circuit, a light source, etc.). Because optical displays generate relatively large amounts of heat, the TIM is used to conduct heat from the heat source (or components in proximity to the heat source that themselves become increasingly hot) to a heat dissipating device, such as a heat sink.

According to various embodiments, the TIM has a heat conductivity of at least 10 W/mK. In some embodiments, the TIM has a length that is equal to or greater than 12 inches, and a width that is equal to or greater than 12 inches. In some embodiments, the TIM has a length up to 12 inches, and/or a width that is up to 12 inches.

According to various embodiments, the TIM has a thickness of between 0.5 mm to 5 mm. The TIM can be about a 12 inch ×12 inch pad with a thickness of between 0.5 mm to 5 mm.

According to various embodiments, the TIM operatively conducts heat from at least −40° C. to at least 150° C. In some embodiments, a heat conductivity of the TIM in an environment at −40° C. is within 10 percent of a heat conductivity of the TIM in an environment at 20° C. In some embodiments, a heat conductivity of the TIM in an environment at −40° C. is within 5 percent of a heat conductivity of the TIM in an environment at 20° C. In some embodiments, a heat conductivity of the TIM in an environment at −40° C. is within 20 percent of a heat conductivity of the TIM in an environment at 20° C. In some embodiments, a heat conductivity of the TIM in an environment at 150° C. is within 10 percent of a heat conductivity of the TIM in an environment at 20° C. In some embodiments, a heat conductivity of the TIM in an environment at 150° C. is within 5 percent of a heat conductivity of the TIM in an environment at 20° C. In some embodiments, a heat conductivity of the TIM in an environment at 150° C. is within 20 percent of a heat conductivity of the TIM in an environment at 20° C.

In some embodiments, the TIM has a dielectric strength of at least 200 V/mil.

Various embodiments disclose a thermal interface material (TIM). The TIM includes a bulk layer. The bulk layer includes a first acrylic rubber, plasticizer particles, and first filler particles, and the first filler particles are substantially aligned in a first direction. The TIM is used in a power supply, automotive electronics, motor control systems, power semiconductors, optical supplies, etc. In some embodiments, a surface of the TIM to which the TIM is applied to a heat source is perpendicular to the first direction. For example, a normal to the surface on which the TIM is applied is parallel to the first direction. The tensile strength of the TIM in the first direction is greater than the tensile strength in a second direction, where the second direction is perpendicular to the first direction. In some embodiments, the tensile strength of the TIM in the first direction is at least 25% greater than the tensile strength of the TIM in the second direction. In some embodiments, the tensile strength of the TIM in the first direction is at least 50% greater than the tensile strength of the TIM in the second direction. In some embodiments, the tensile strength of the TIM in the first direction is at least 15% greater than the tensile strength of the TIM in the second direction. In some embodiments, the foregoing TIM is pliable (e.g., the TIM is suitable for conforming to surface, such as a curved surface).

Various embodiments disclose a thermal interface material (TIM). The TIM includes a bulk layer and at least one adhesive layer. The bulk layer includes a first acrylic rubber, plasticizer particles, and first filler particles, and the first filler particles are substantially aligned in a first direction. A first adhesive layer of the at least one adhesive layer is disposed on a first side of the bulk material. The first adhesive layer has a greater tackiness than the bulk material. The first adhesive layer comprises a second acrylic rubber. The first direction is substantially perpendicular to a first surface of the first side on which the first adhesive layer is disposed. In some embodiments, the first adhesive layer is applied (e.g., to the bulk layer) by a pressure sensitive adhesive (e.g., by spraying or rolling). In some embodiments, the first adhesive layer is as a polymer solution that is applied to the bulk layer.

Spraying the adhesive (e.g., a polymer solution) onto a surface of the bulk layer allows for very thin layers of the adhesive to be applied. In some embodiments, the at least one adhesive layer has a thermal conductivity less than the thermal conductivity of the of the bulk layer.

Various embodiments disclose a thermal interface material (TIM). The TIM includes a bulk layer and at least one adhesive layer. The bulk layer includes a first acrylic rubber, plasticizer particles, and first filler particles, and the first filler particles are substantially aligned in a first direction. A first adhesive layer of the at least one adhesive layer is disposed on a first side of the bulk material. The first adhesive layer has a greater tackiness than the bulk material. The first adhesive layer comprises a second acrylic rubber. The first direction is substantially perpendicular to a first surface of the first side on which the first adhesive layer is disposed. In some embodiments, the thermal conductivity of the at least one adhesive layer is less than the thermal conductivity of the bulk layer. As an example, the thermal conductivity of the first adhesive is at least 10 percent less than the thermal conductivity of the bulk layer. As another example, the thermal conductivity of the first adhesive is at least 25 percent less than the thermal conductivity of the bulk layer. As an example, the thermal conductivity of the first adhesive is at least 50 percent less than the thermal conductivity of the bulk layer.

In some embodiments, if the heat source is a relatively hard material, the at least one adhesive is a polymer solution that is applied via spraying the polymer solution onto a surface of the bulk layer. A relatively hard material may be a material having greater than 70 pts Shore 00.

In some embodiments, the TIM has a thermal conductivity of at least 15 W/m*K as measured by ASTM D5470 (at 20 psi). In some embodiments, the TIM has a thermal conductivity of 17 W/m*K as measured by ASTM D5470 (at 20 psi). In some embodiments, the TIM has a thermal resistance vs pressure of at least 0.95 K cm²/W @ 140 kPa (20 psi) as measured by ASTM D5470. In some embodiments, the TIM has a thermal resistance vs pressure of 0.96 K cm²/W @ 140 kPa (20 psi) as measured by ASTM D5470. In some embodiments, the TIM has a compression deflection of at least 10% @ 210 kPa (30 psi) as measured by a modified ASTM C165 method. In some embodiments, the TIM has a compression deflection of at least 15% @ 210 kPa (30 psi) as measured by a modified ASTM C165 method. In some embodiments, the TIM has a compression deflection of 15% @ 210 kPa (30 psi) as measured by a modified ASTM C165 method. In some embodiments, the TIM has an operating temperature of between −40° C. and 135° C. In some embodiments, the TIM has a hardness of between 70 and 90 Shore 00 as measured by ASTM D2240. In some embodiments, the TIM has a hardness of at least 75 Shore 00 as measured by ASTM D2240. In some embodiments, the TIM has a hardness of less than 100 Shore 00 as measured by ASTM D2240. In some embodiments, the TIM has a hardness of between 77 and 87 Shore 00 as measured by ASTM D2240. In some embodiments, the TIM has a specific gravity of at least 1.5 g/cm² as measured substantially in accordance with a method based on ASTM D792. In some embodiments, the TIM has a specific gravity of at least 1.70 g/cm² as measured substantially in accordance with a method based on ASTM D792. In some embodiments, the TIM has a specific gravity of 1.71 g/cm² as measured substantially in accordance with a method based on ASTM D792. In some embodiments, the TIM has a specific gravity of less than 2.0 g/cm² as measured substantially in accordance with a method based on ASTM D792.

In some embodiments, the TIM has a thermal conductivity of at least 20 W/m*K as measured by ASTM D5470 (at 20 psi). In some embodiments, the TIM has a thermal conductivity of at least 25 W/m*K as measured by ASTM D5470 (at 20 psi). In some embodiments, the TIM has a thermal conductivity of at least 30 W/m*K as measured by ASTM D5470 (at 20 psi). In some embodiments, the TIM has a thermal conductivity of 35 W/m*K as measured by ASTM D5470 (at 20 psi). In some embodiments, the TIM has a thermal resistance vs pressure of at least 0.25 K cm²/W @ 140 kPa (20 psi) as measured by ASTM D5470. In some embodiments, the TIM has a thermal resistance vs pressure of at least 0.40 K cm²/W @ 140 kPa (20 psi) as measured by ASTM D5470. In some embodiments, the TIM has a thermal resistance vs pressure of 0.45 K cm²/W @ 140 kPa (20 psi) as measured by ASTM D5470. In some embodiments, the TIM has a thermal resistance vs pressure of less than 0.90 K cm²/W @ 140 kPa (20 psi) as measured by ASTM D5470. In some embodiments, the TIM has a thermal resistance vs pressure of less than 0.75 K cm²/W @ 140 kPa (20 psi) as measured by ASTM D5470. In some embodiments, the TIM has a thermal resistance vs pressure of less than 0.50 K cm²/W @ 140 kPa (20 psi) as measured by ASTM D5470. In some embodiments, the TIM has a compression deflection of at least 10% @ 210 kPa (30 psi) as measured by a modified ASTM C165 method. In some embodiments, the TIM has a compression deflection of at least 15% @ 210 kPa (30 psi) as measured by a modified ASTM C165 method. In some embodiments, the TIM has a compression deflection of 15% @ 210 kPa (30 psi) as measured by a modified ASTM C165 method. In some embodiments, the TIM has an operating temperature of between −40° C. and 150° C. In some embodiments, the TIM has a hardness of between 70 and 90 Shore 00 as measured by ASTM D2240. In some embodiments, the TIM has a hardness of at least 75 Shore 00 as measured by ASTM D2240. In some embodiments, the TIM has a hardness of less than 100 Shore 00 as measured by ASTM D2240. In some embodiments, the TIM has a hardness of between 77 and 83 Shore 00 as measured by ASTM D2240. In some embodiments, the TIM has a specific gravity of at least 1.5 g/cm² as measured substantially in accordance with a method based on ASTM D792. In some embodiments, the TIM has a specific gravity of at least 1.70 g/cm² as measured substantially in accordance with a method based on ASTM D792. In some embodiments, the TIM has a specific gravity of 1.70 g/cm² as measured substantially in accordance with a method based on ASTM D792. In some embodiments, the TIM has a specific gravity of less than 2.0 g/cm² as measured substantially in accordance with a method based on ASTM D792. In some embodiments, the TIM has a specific gravity of less than 1.75 g/cm² as measured substantially in accordance with a method based on ASTM D792.

According to various embodiments, the TIM does not include silicone. For example, the TIM is a non-silicone, non-reactive, non-curing system with no resin-filler separation.

Various embodiments include a TIM that has high thermal stability with continuous operation up to at least about 135° C. The TIM according to various embodiments has a relatively low density, which improves the lightweighting of the TIM and devices in which the TIM is comprised. The TIM allows reworkability of the thermal interface management system. In some embodiments, the TIM provides for an easy pick and place application with a tacky surface to facilitate manufacturing. In some embodiments, the TIM is relatively highly compressible, which may improve the minimization of contact resistance without high force and component stress.

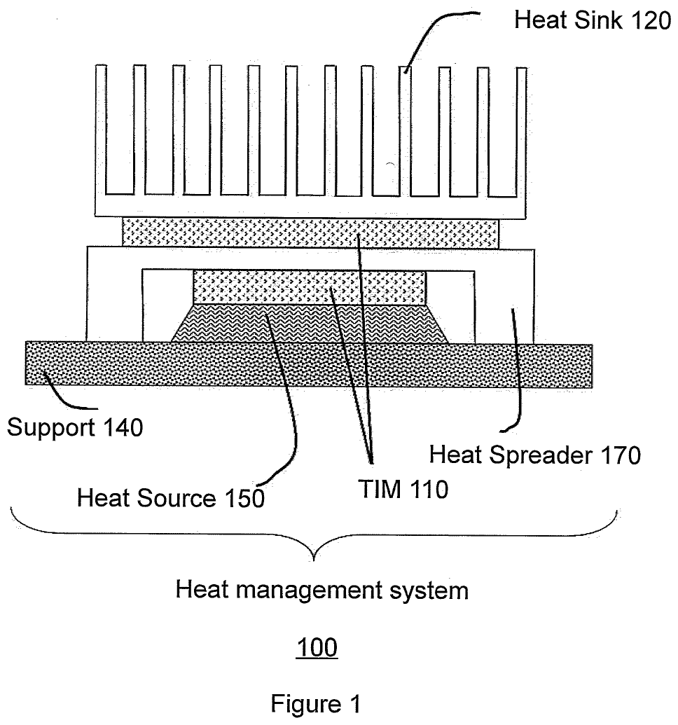

FIG. 1 is a schematic diagram depicting aspects of a heat generating component, a heat sink and use of thermal interface materials.

In the heat management system 100 shown, a heat source 150 generates heat. Non-limiting examples of the heat source 150 include a least one of a processor, memory, a power supply, a power converter, a light emitting diode and a laser diode. Generally, the heat source 150 is mounted to a support 140. A non-limiting example of the support 140 is a printed circuit board (PCB). In this illustration, the heat source 150 is surface mounted onto the support 140. A first deposition of thermal interface material (TIM) 110 is directly on top of and in thermal communication with the heat source 150. A heat spreader 170 is disposed over the first deposition and in thermal communication therewith. On top of the heat spreader 170 and in thermal communication therewith is a second deposition of thermal interface material (TIM) 110. A heat sink 120 is disposed over the second deposition and in thermal communication therewith.

When energized, the heat source 150 generates heat. The heat is conducted away from the heat source 150 by the depositions of thermal interface material (TIM) 110 along with the heat spreader 170 and the heat sink 120. Generally, the depositions of thermal interface material (TIM) 110 enhance heat conduction between the heat source 150 and the heat sink 120 by elimination of gaps and air space between the components.

Generally, the heat sink 120 is a traditional cooling solution that maximizes the surface area (using fins or pins) and airflow (using fans) to dissipate heat from the heat source 150 out into the surrounding air. The heat sink 120 may be built with cooling fans as a simple, lightweight, and completely self-contained cooling solution. Depending on the available airflow, the heat sink 120 can often out-perform a similar sized heat spreader 170.

Generally, the heat spreader 170 has a large, flat surface on top. In some embodiments, the heat spreader 170 has no fan and no fins. The heat spreader 170 may be pressed directly up against another large flat surface (for example: the frame of a vehicle or the inside wall of a sealed container) and heat is allowed to pass from the heat spreader 170 out to the larger metal (thermally conductive) surface. In typical designs, the heat spreader 170 does not cool the heat source 150 (e.g., a CPU) alone. Rather, the heat spreader 170 is designed to transfer the heat to another object where it can safely dissipate away from the heat source 150. Generally, heat spreaders 170 are ideal for electronics systems that expect to operate under extreme shock and vibration, or systems that need to be completely sealed inside a container to be protected from the environment. Understandably, the performance of the heat sink 120 and the heat spreader 170, and thus the heat source 120 (such as a processor) may be substantially influenced by performance of the thermal interface material (TIM) 110.

It may be readily apparent that in the heat management system 100 of FIG. 1, having thermal interface material (TIM) 110 available as a pad may speed assembly and provide for consistent quality. That is, for example, dispending thermal interface material (TIM) 110 in the form of a grease or paste will require volume control as well as consistent spreading. In contrast, by designing the thermal interface material (TIM) 110 for implementation as a pad having suitable physical properties, superior quality control may be achieved.

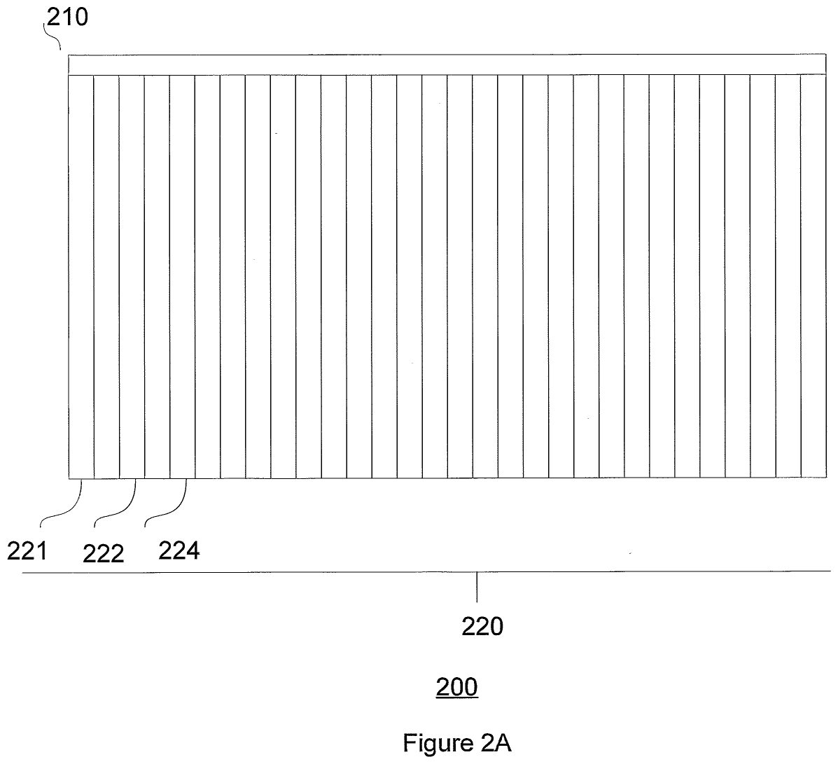

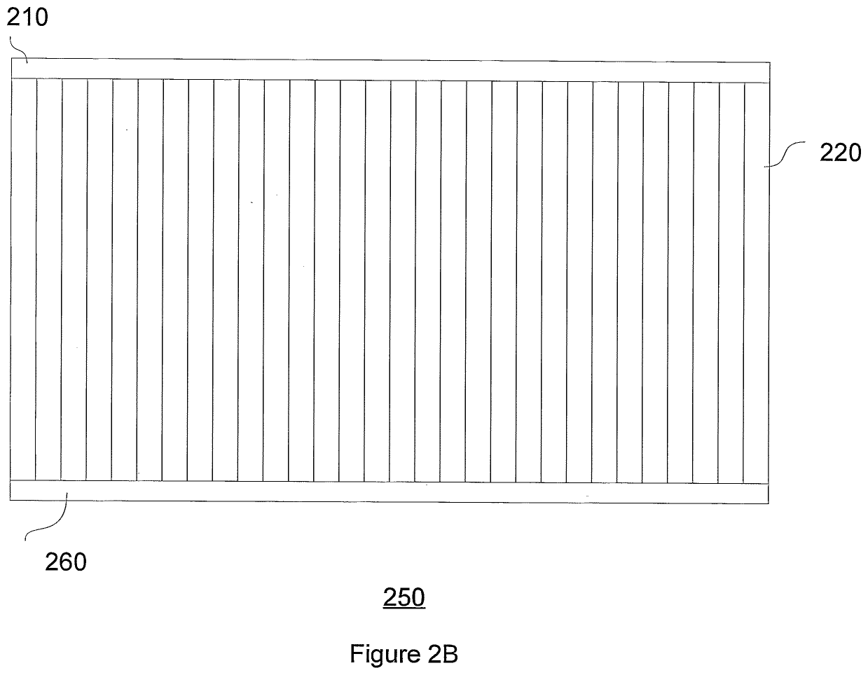

FIG. 2A is a diagram of a thermal interface material according to various embodiments. In the example shown, TIM 200 includes an adhesive layer 210 and a bulk layer 220. As illustrated in FIG. 2A, bulk layer 220 may comprise a plurality of layers 221, 222, 224. Adhesive layer 210 can be comprised on at least one side of bulk layer 220.

According to various embodiments, as illustrated in FIG. 2A, a first adhesive layer 210 is applied to a surface of bulk layer 210 that is substantially perpendicular to an interface between the various layers of bulk layer 220. For example, first adhesive layer 210 is applied to a surface that is perpendicular to (i) an interface between layer 221 and a layer adjacent to layer 221, (ii) an interface between layer 222 and a layer adjacent to layer 222, and/or (iii) an interface between layer 224 and a layer adjacent to layer 224, etc.

FIG. 2B is a diagram of a thermal interface material according to various embodiments. In the example shown, TIM 200 includes a plurality of adhesive layers comprised on different sides of bulk layer 220. For example, TIM 200 comprises a first adhesive layer 210 on a first side of bulk layer 220, and a second adhesive layer 260 on a second side of bulk layer 220. The first side and the second side may be opposite sides of bulk layer 220. In some embodiments, the first adhesive layer 210 and the second adhesive layer 220 are on respective sides of bulk layer 220 that is perpendicular to an interface between layers comprised in bulk layer 220. For example, first adhesive layer 210 and second adhesive layer 220 is applied to a surface that is perpendicular to (i) an interface between layer 221 and a layer adjacent to layer 221, (ii) an interface between layer 222 and a layer adjacent to layer 222, and/or (iii) an interface between layer 224 and a layer adjacent to layer 224, etc.

Referring to FIGS. 2A and 2B, according to various embodiments, first adhesive layer 210 and/or second adhesive layer 260 are polymer solution that is applied to bulk layer 220. For example, the polymer solution is applied using a spraying or rolling process. As another example, the polymer solution is applied using an electro spinning or electro spraying process.

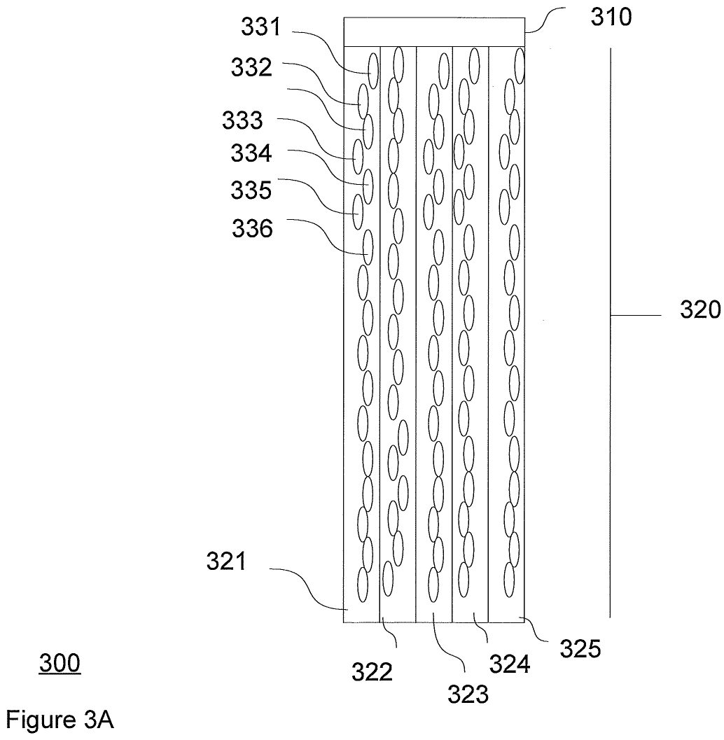

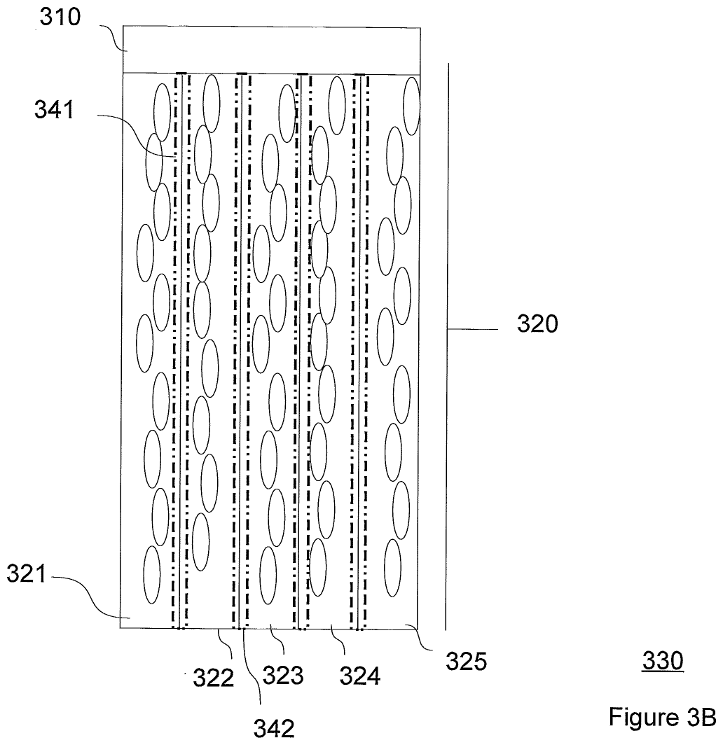

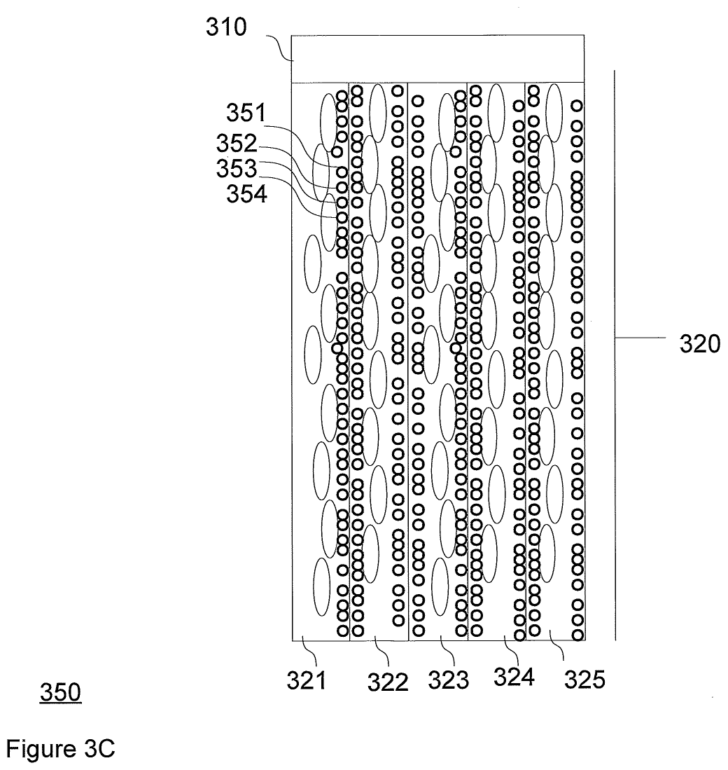

FIG. 3A is a diagram depicting aspects of a thermal interface material according to various embodiments. In the example shown, TIM 300 includes an adhesive layer 310 and a bulk layer 320. As illustrated in FIG. 3A, bulk layer 320 may comprise a plurality of layers 321, 322, 323, 324, 325. Adhesive layer 310 can be comprised on at least one side of bulk layer 320. Adhesive layer 310 can correspond to, or is similar to, adhesive layer 210 of TIM 200 of FIG. 2A.

According to various embodiments, the bulk layer 210 is manufactured according to processes further described herein, or the process further described in U.S. patent application Ser. No. 17/165,363 filed on Feb. 2, 2021, the entirety of which is hereby incorporated herein for all purposes. In some embodiments, a master batch of bulk material comprised in bulk layer 320 is extruded to form a sheet or film having a predefined thickness. One or more sheets of the bulk material are cut to obtain a predefined size/shape of the bulk material (also referred to herein as bulk material segments). Thereafter, a plurality of bulk material segments are stacked and compressed to form a bulk material aggregate. The bulk material aggregate is then sliced in a direction that is perpendicular to the interfaces between pairs of the plurality of bulk material segments to obtain bulk layer 320 (e.g., a TIM pad).

Thereafter, the adhesive layer may be applied to one or more sides of bulk layer 320, such as using the processes described above with respect to TIM 200.

As illustrated in FIG. 3A, bulk layer 320 comprises a first acrylic rubber, plasticizer particles, and first filler particles, and the first filler particles are substantially aligned in a first direction. For example, bulk layer 320 comprises a first filler particles 331, 332, 334, 335, and 336. As shown in FIG. 3A, first filler particles 331, 332, 334, 335, and 336 are substantially aligned in a first direction. Bulk layer may comprise a plurality of layers, such as layer 321, layer 322, layer 323, layer 324, and/or layer 325. The first direction can correspond to a direction that is (substantially) parallel with the interface between the layers of bulk layer 320 (e.g., an interface or surface at which layer 321 is affixed to layer 322, or at which layer 322 is affixed to 323, etc.). The filler particles may be aligned based at least in part on an extrusion process used to extrude the bulk material.

FIG. 3B is a diagram depicting aspects of a thermal interface material according to various embodiments. According to various embodiments, thermal interface material comprises one or more channels of air that extend along a first direction. The first direction can be parallel (or substantially parallel) to the interface between the layers of the bulk layer. In some embodiments, the one or more channels extend along the first direction.

In some embodiments, the one or more channels are comprised in, adjacent to, or otherwise in proximity to, to the interface between the layers of the bulk layer.

Referring to FIG. 3B, TIM 300 comprises air channels 341 and 342. Air channel 341 is comprised in, adjacent to, or otherwise in proximity to, to the layer 321 and layer 322 of the bulk layer 320. As an example, the air channel 341 may be formed when a bulk material segment corresponding to layer 321 and a bulk material segment corresponding to layer 322 are compressed or otherwise affixed to one another.

Related art TIMs are generally a bulk or composite that is uniform throughout the material. The presence of one or more channels (e.g., air channels) may improve the weight of the TIM. For example, the density of the air or other gas comprised within the one or more channels is less than the density of the bulk material of the bulk layer 320.

FIG. 3C is a diagram depicting aspects of a thermal interface material according to various embodiments. According to various embodiments, thermal interface material comprises one or more channels of air that extend along a first direction. The first direction can be parallel (or substantially parallel) to the interface between the layers of the bulk layer. In some embodiments, the one or more channels extend along the first direction.

In some embodiments, the one or more channels are comprised in, adjacent to, or otherwise in proximity to, to the interface between the layers of the bulk layer.

Referring to FIG. 3C, TIM 300 comprises gas bubbles (e.g., air bubbles) comprised in the interface between two of the layers of the bulk layer 320, or otherwise adjacent or in proximity to such interface. For example, gas bubbles 351, 352, 353, and 354 are comprised in, or adjacent to, the interface between layer 321 and layer 322. As an example, the bubbles 351, 352, 353, and 354 may be formed when a bulk material segment corresponding to layer 321 and a bulk material segment corresponding to layer 322 are compressed or otherwise affixed to one another.

According to various embodiments, the introduction of channels (e.g., air channels), or bubbles can be emphasized by performing a surface treatment of the bulk material segments respectively corresponding to layers of a bulk layer that is being assembled. For example, the surface of a bulk material segment may be scored or a plurality of indentations may be made to the surface.

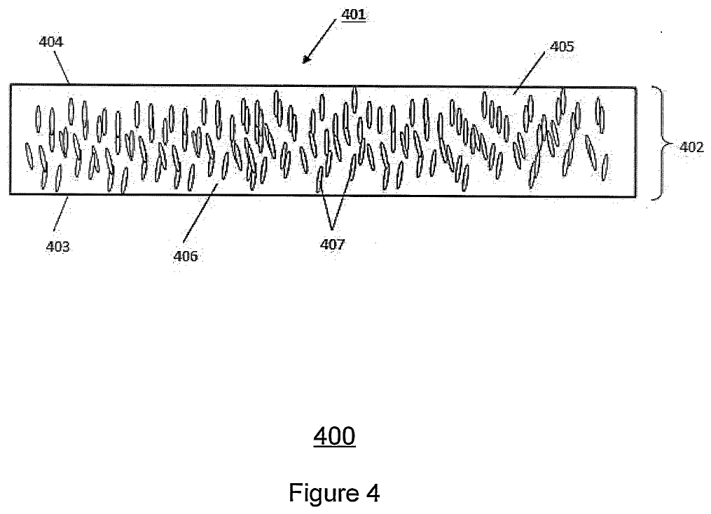

FIG. 4 is a schematic diagram of a thermal interface material pad according to various embodiments. Referring to FIG. 4, an example thermal interface material (TIM) 401 is shown. The TIM 401 is formed as a pad or sheet 402 extending between a first major surface 403 (as shown the bottom surface) and a second major surface 404 (as shown the top surface). Although a flat sheet is shown, it will be apparent to one skilled in the art that other shapes may be used, such as a curved sheet, or a sheet cut to custom shape and dimensions as desirable for a given application.

The sheet 402 is formed of a base material 405 with a thermally conductive filler material 406 embedded in the base material.

The base material 405 may be a material chosen to have desired mechanical and thermal properties. Numerous exemplary suitable materials are set forth below. For the purpose of the depicted exemplary embodiment, the base material will be considered to be an acrylic rubber or acrylic resin material. In some embodiments, the base material 405 may be a mixture of components such as resin combined with a plasticizer material.

Advantageously, in some embodiments, the base material may be free or substantially free of silicones or other siloxane-based polymers which are known to exhibit degradation, outgassing, and other undesirable properties at high temperature.

As shown, the filler material 406 may include anisotropically oriented thermally conductive elements 407. The thermally conductive elements 407 may be preferentially oriented along a primary direction from the first major surface 403 towards the second major surface 404 (as shown, the vertical direction) to promote thermal conduction though the sheet along the primary direction.

In some embodiments, the inclusion of the filler provides for excellent thermal conductivity through the sheet 402 along the primary direction. For example, in some embodiments, the thermal conductivity of the sheet along the primary direction is at least 10 W/mK, 15 W/mK, 30 W/mK, 40 W/mK, 50 W/mK, 60 W/mK, 70 W/mK, 80 W/mK, 90 W/mK, 100 W/mK, or more. In some embodiments, the thermal conductivity may be measured using the ASTM standard D5470 known in the art.

In some embodiments, the TIM 401 exhibits excellent thermal impedance as a function of applied pressure. For example, in some embodiments this property may be measured using the techniques described in the ASTM standard D5470 known in the art, resulting in a thermal impedance at 10 psi pressure of less than 0.1° C.-inch2/W, 0.09° C.-inch2/W, 0.08° C.-inch2/W, 0.07° C.-inch2/W, 0.05° C.-inch2/W, or less (e.g., for a sheet with thickness in the range of 0.5 mm to 5.0 mm). For example, in some embodiments this property may be measured using the techniques described in the ASTM standard D5470 known in the art, resulting in a thermal impedance at 30 psi pressure of less than 0.06° C.-inch2/W, 0.05° C.-inch2/W, 0.04° C.-inch2/W, 0.03° C.-inch2/W, 0.02° C.-inch2/W, 0.01° C.-inch2/W or less (e.g., for a sheet with thickness in the range of 0.5 mm to 5.0 mm).

In some embodiments, the sheet 402 may be self-supporting, e.g., formed from a flexible polymer resin base material 405. In some embodiments, the sheet may have a thickness in the range of 0.1 mm to 10 mm, or any subrange thereof, e.g., 0.5 mm to 5.0 mm. In some embodiments. TIM 401 may exhibit at Shore hardness in the range of 40 to 90 or any [symbol] subrange thereof such as of 50 to 80 or 60 to 70, as determined by the techniques set forth in ASTM D2240 (Shore 00).

In some embodiments the TIM 401 may have a density in the range of 0.5 g/mL to 5.0 g/mL or any subrange thereof, e.g., 1.0 g/mL to 2.0 g/mL. In some embodiments, the TIM 401 may have a density of about 1.7 g/mL.

In some embodiments, the TIM 401 exhibits desirably high deflection as a function of applied pressure. In some such embodiments, this property allows for excellent thermal contact between the TIM 401 and other thermal sources and sinks in applications where pressure is applied. In some deflection as a function of compression may be measured using the techniques of the ASTM D5470 and ASTM C165 standards known in the art. In some embodiments, the TIM 402 exhibits a deflection of at least 10%, 20%, 30%, 40%, 50%, 60%, or more at a compression pressure of 30 psi, and a deflection of at least 30%, 40%, 50%, 60%, 70%, 80%, or more at a pressure of 50 psi.

In some embodiments, the TIM 401 can operate at temperature in the range of −40° C. to 150° C. without significant degradation. For example, in some embodiments the TIM 401 exhibits a total mass loss of less than 0.2% at temperatures at or above 150° C., 160° C., 170° C., 180° C., or more under thermogravimetric analysis using the techniques set forth in the ASTM E595 standard known in the art.

In some embodiments, the filler material may include ceramic flakes such as boron nitride flakes. In some embodiments, the filler material may include boron nitride nanoflakes or nanoscrolls.

In some embodiments, the filler material may include carbons such as graphite flakes or graphene flakes. In some embodiments, the filler material may include carbon nanotubes, bundles of carbon nanotubes, and agglomerates of aligned carbon nanotubes. Other suitable examples of filler material are presented in the examples below.

In some embodiments, the anisotropically oriented thermally conductive elements include flake shaped elements having a major surface, and at least 65%, 75%, 85%, 95%, 99% or more of the flake shaped elements are aligned such that the major surface substantially lies in a plane extending along the primary direction transverse to the first and second surfaces of the sheet. For example, as show in FIGS. 1, 3A, 3B, and 3C, the vast majority of the conductive elements are oriented such that the major surface of the flakes are oriented transverse to the top and bottom surface.

In some embodiments, the anisotropically oriented thermally conductive elements include elongated elements (e.g., carbon nanotubes) having a major [symbol] dimension and one or more minor dimensions and wherein at least 65%, 75%, 85%, 95%, 99% or more of the elongated elements are aligned such that the major dimension extends along the primary direction transverse to the first and second surfaces of the sheet.

In various embodiments, the amount of filler material used may be selected to result in desired properties. In general, a larger amount of filler will tend to provide higher thermal conductivity (provided sufficient care in taken to ensure that the filler does not result in unwanted surface roughness, as detailed below). In some embodiments, the filler is at least 20%, 30% 40%, 50%, 60%, 70%, 80%, 90%, 95% or more by weight of the sheet.

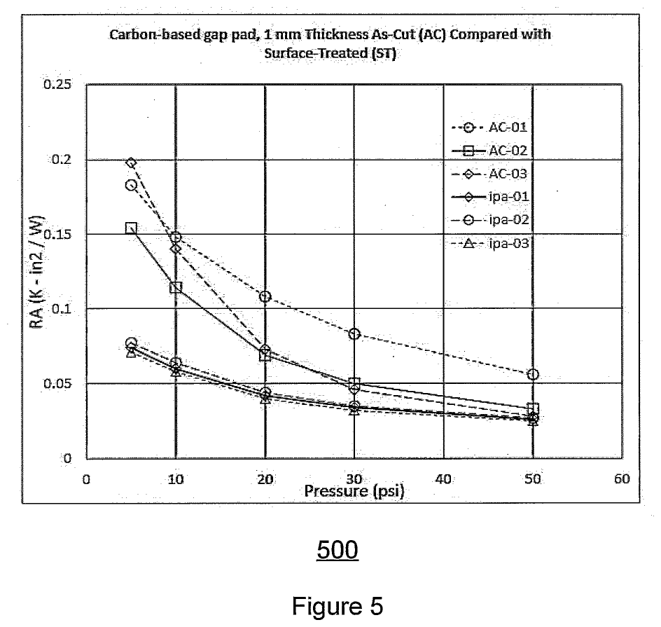

FIG. 5 is a plot of thermal impedance vs. pressure for six samples of thermal interface material pads. The upper three traces show results for samples without surface treatment. The lower three traces show results for samples with surface treatment of an adhesive.

Six samples of the TIM (e.g., TIM 200 of FIG. 2A, TIM 300 of FIG. 3A, etc.) were made, each having a thickness of 1.0 mm. The samples were tested for thermal impedance at various pressures, using the techniques set forth in the ASTM standard D5470 know in the art. Three of the samples underwent surface treatment to improve surface treatment, three did not. As shown in FIG. 5, the thermal impedance for the treated samples (lower traces) was less than that of the untreated samples (upper traces), especially at low pressure. This clearly indicates that the surface treatment promotes better thermal contact between the TIM 101 and the heat sources and sinks used in the evaluation.

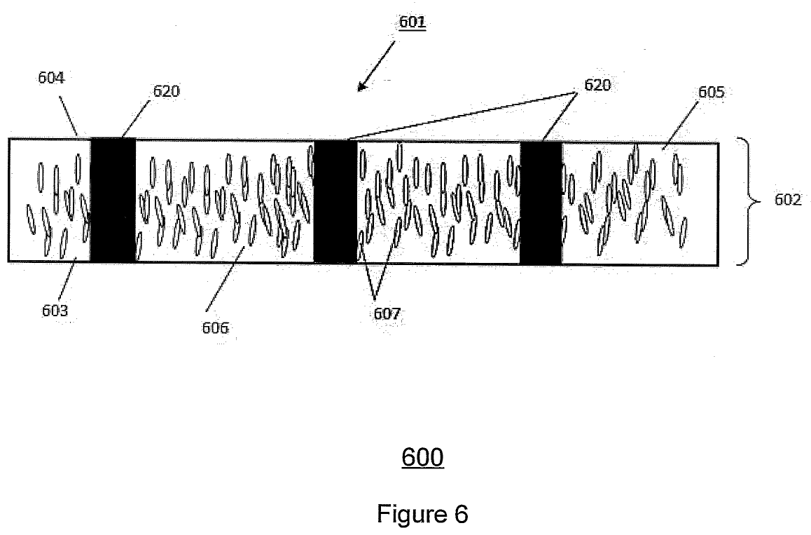

FIG. 6 is a schematic diagram of a thermal interface material pad according to various embodiments. Referring to FIG. 6, in some embodiments, the TIM 601 includes thermally conductive elements 620 extending through the sheet 602 from the first major surface 603 to the second major surface 604 along the primary direction (as shown the vertical direction). These thermally conductive elements may promote heat flow between the surfaces 603, 604. In some embodiments, these elements 620 may be made of carbon. For example, graphite or graphene formed as sheets, strips, pillars, or other suitable shapes may be used.

In some embodiments, a portion of the thermally conductive elements may be exposed at the first and second major surfaces 603, 604 of the sheet 602. In some such cases it may be desirable to treat the surface to protect these regions, e.g., by using the solvent based surface treatment described above, or by applying a thin protective adhesive layer to the surfaces 603, 604.

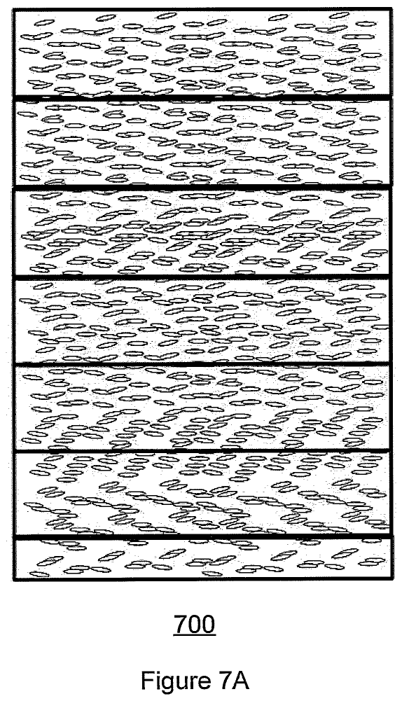

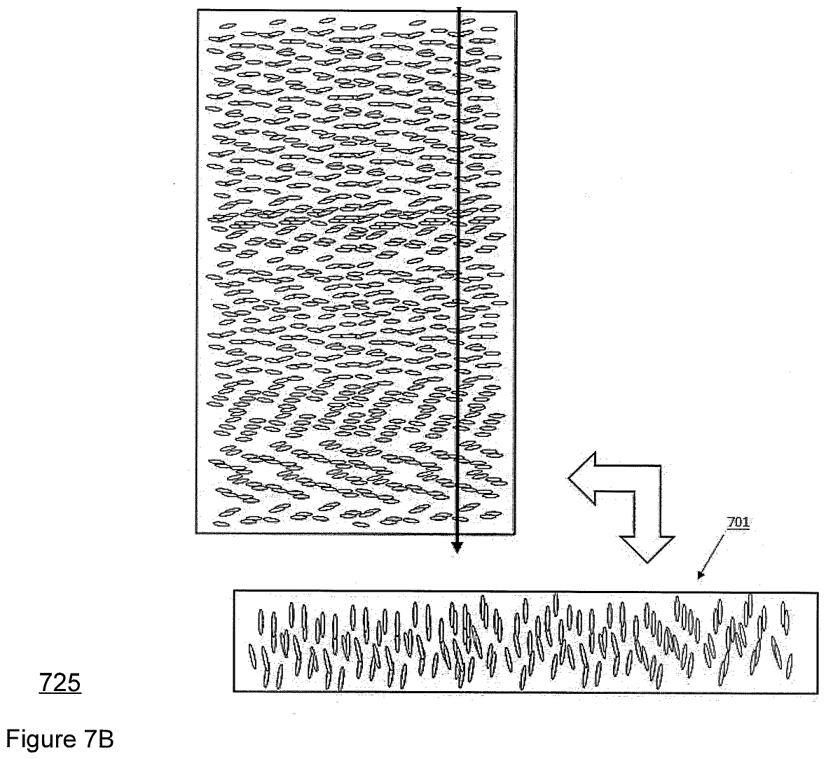

FIG. 7A is an illustration of the initial steps in a method of fabrication of a thermal interface pad according to various embodiments. FIG. 7B is an illustration of the final steps in a method of fabrication of a thermal interface pad according to various embodiments.

Referring to FIG. 7A, a stack is formed at includes a plurality of layers. The plurality of layers can correspond to layers of a bulk layer of a TIM.

Each layer extends from a bottom surface to a top surface along a direction (as shown, the vertical direction), and the layers are stacked one above the other in that direction.

Each layer includes a base material, and a filler material of the type described above with reference to FIGS. 2A, 2B, 3A, 3B, and 3C. The filler material in each layer is made up of anisotropically oriented thermally conductive elements. However, unlike in the sheet used in the final TIM, the elements are oriented to promote heat flow directions transverse to the vertical direction from the bottom surface to the top surface rather than along it. Accordingly, these layers in the stack are not suitable for use as the TIM in FIG. 2A, 2B, 3A, 3B, and 3C without further processing.

Referring to FIG. 6, accordingly, in some embodiments, force may be applied (optionally along with heat) in the vertical direction to compress the stack to cause the layers to join together to form a monolithic element. The monolithic element may comprise a plurality of channels (e.g., air channels or bubbles such as gas bubbles or pockets). The stack may be sliced, e.g. using a fine blade, or ultrasonic or laser cutting along a plane extending in the vertical direction (indicated in FIG. 7B with a heavy dark arrow) to form a sheet of a desired thickness. This sheet is removed from the stack and forms a TIM such as the TIMs illustrated in FIGS. 2A, 2B, 3A, 3B, and 3C. Notably, the TIM now includes a sheet having filler material made up of anisotropically oriented thermally conductive elements oriented in the proper direction. For example, the sheet extends between a first major surface and a second major surface, and the filler material includes anisotropically oriented thermally conductive elements that are preferentially oriented along a primary direction from the first major surface towards the second major surface to promote thermal conduction though the sheet along the primary direction.

Additional slices may be taken to generate additional TIM pads. In other words, the stacking and slicing process described above takes a plurality of layers in which the filler material has an anisotropic orientation in a direction unsuitable for use as a TIM and generates a number of TIM pads with the filler having the desired orientation.

[symbol]

As described in detail below, the layers can be generated using a simple process suitable for mass production techniques. For example, in some embodiments each stack layer can be formed by providing a mixture of base material and filler material that includes the thermally conductive elements. In general, this mixture can be made without taking any steps to orient the filler material, resulting in an isotropic distribution of the thermally conductive elements in the base material. The resulting mixture can then be physically manipulated to cause the thermally conductive elements to become anisotropically oriented within the layer. For example, as described in detail in the additional examples below, the mixture can be extruded to form the layers, compressed to form the layers, repeatedly folded on itself to form the layer, or combinations thereof.

As described above, this physical manipulation will result in a layer having anisotropically oriented thermally conductive elements oriented in an undesirable direction for use in the TIM. However, this can be rectified by performing the stacking, compression, and slicing steps describe above with reference to FIG. 7A and 7B.

In some embodiments, the base material is a self-healing material, thereby promoting the melding of the layers into a monolithic element during the compression step provided above. Self healing materials are also advantageous in that they resist damage (e.g., cracking) that may occur during the slicing step described above with reference to FIG. 7B.

In various embodiments, the method may further include applying a surface treatment to one or more of the major surfaces of the TIM, such as one or more adhesive layers as further described herein.

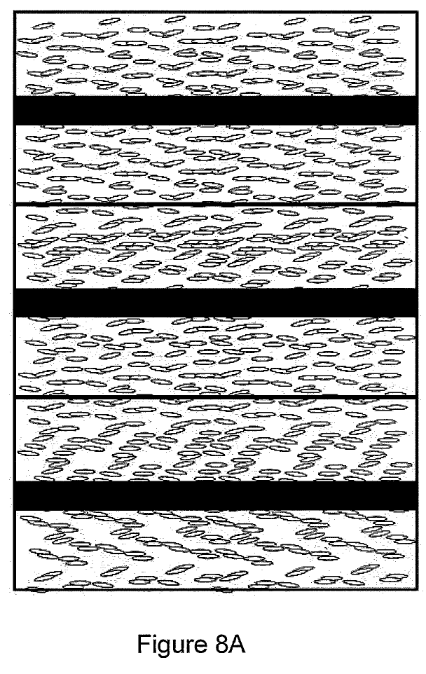

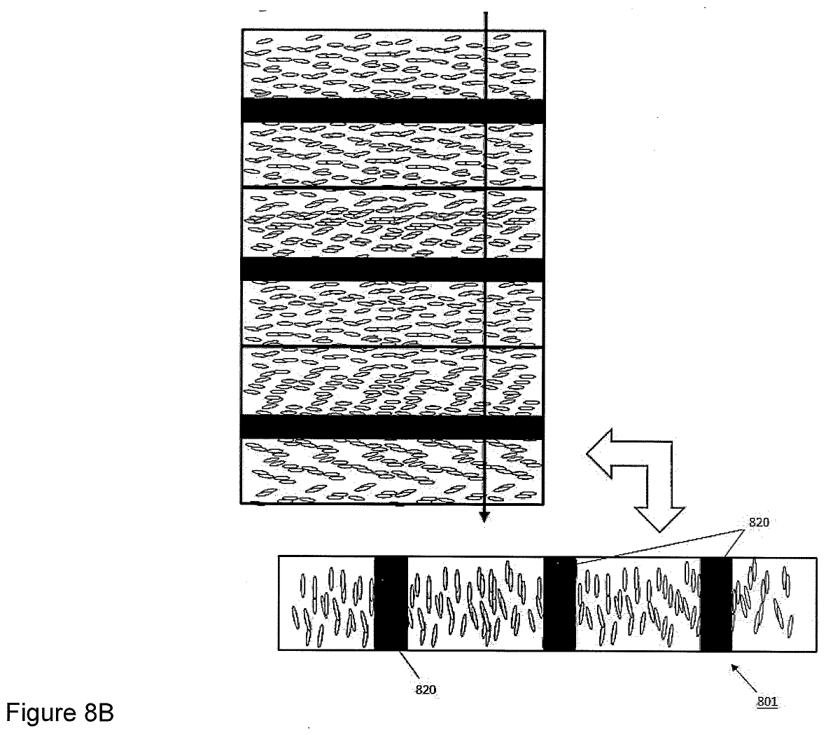

FIG. 8A is an illustration of the initial steps in a method of fabrication of a thermal interface pad according to various embodiments.

According to various embodiments, a thermally conductive composition may include fillers for example, metal powder and mixtures thereof (for example, aluminum powder; silver powder; copper powder); graphite flakes, ceramic powder (for example, alumina; boron nitride and others). The composition may also include a self-supporting base material that includes materials such as rubbers (e.g., acrylic rubber), oils, polymers, thermoplastic resins and thermoset resins. Generally, the thermally conductive composition may be fabricated from materials exhibiting suitable properties. The properties may include, for example, pliability and good thermal conductivity. A variety of other materials may be used.

In some embodiments, a thermoplastic resin that is substantially solid at room temperature is used. Some examples of suitable thermoplastic resins include, acrylic resin, epoxy resin, silicone resin, fluorine resin and the like. These may be used alone, or in combination with other materials (as practicable).

The thermoplastic resin may be used in combination with a solid. Thermoplastic polymers/resins which may be used include, for example, poly (2-ethylhexyl acrylate), 2-ethylhexyl acrylate-acrylic acid copolymer, a polymethacrylic acid or its ester, an acrylic resin such as a polyacrylic acid or its ester; silicone resins; fluororesins; polyethylene; polypropylene; ethylene-propylene copolymer; polymethylpentene; polyvinyl chloride; polyvinyl acetate; ethylene-vinyl acetate copolymer; polyvinyl alcohol; polyacetal; polyethylene terephthalate; polyethylene; polystyrene; polyacrylonitrile; styrene acrylonitrile copolymer; acrylonitrile-butadiene-styrene (ABS resin)-copolymer; styrene butadiene block copolymer or its hydrogenated product; styrene-isoprene block co-polymer copolymer or its hydrogenated product; polyphenylene ether; modified polyphenylene ether; aliphatic polyamide; and aromatic polyamides; polyamide; polycarbonate; polyphenylene sulfide; polysulfone; polyethersulfone; polyethernitrile; polyetherketones; polyketone; polyurethane; liquid crystal polymer; ionomers; and the like. These may be used alone, or in combination with other materials (as practicable).

In some embodiments, a thermoplastic fluorocarbon resin is used. This may result in certain other advantages, such as improved heat resistance, oil resistance, and chemical resistance.

Solid thermoplastic fluororesin that may be useful include, for example, vinylidene fluoride, tetrafluoroethylene-propylene, tetrafluoroethylene-system or the like, fluorine-containing polymerizable monomer of the resulting elastomer and the like. More specifically, a poly-tetrafluoroethylene, a tetrafluoroethylene-perfluoroalkylvinyl ether copolymer, tetrafluoroethylene-hexafluoropropylene copolymer, tetrafluoroethylene-ethylene copolymer, polyvinylidene fluoride, polychlorotrifluoroethylene, ethylene-copolymer, tetrafluoroethylene-copolymer, polyvinylfluorides, tetrafluoroethylene-propylene copolymer, tetrafluoroethylene-hex-afluoropropylene copolymer, acrylic-modified polytetrafluoroethylene, polytetrafluorocthylene modified ester, epoxy-modified silane-modified polytetrafluoroethylene and polytetrafluoroethylene and the like.

Additional materials that may be used as the thermoset resin include, for example, natural rubber; acrylate rubber; butadiene rubber; isoprene rubber; nitrile rubber; hydrogenated nitrile rubber; chloroprene rubber; ethylene-propylene rubber; chlorinated [symbol] polyethylene; chlorosulfonated polyethylene; butyl rubber; halogenated butyl rubber; polyisobutylene rubber; polyacrylic rubber; epoxy resin; a polyimide resin; a bismaleimide resin; benzocyclobutene resin; a phenol resin; unsaturated polyester; a diallyl phthalate resin; a polyimide resin; a polyurethane; a thermosetting polyphenylene ether; thermosetting polyphenylene ether; and the like.

In some embodiments, the thermally conductive composition includes poly(vinyl acetate) (PVA) or poly(ethenyl ethanoate) (PVAc). Generally, PVA is an aliphatic rubbery synthetic polymer with the formula (C₄H₆O₂)ₙ. PVA belongs to the polyvinyl esters family, with the general formula -[RCOOCHCH₂]- and is a type of thermoplastic. In some embodiments, the thermally conductive composition is a non-silicone base material. One additional example includes a soy-oil base material.

Any of the foregoing materials may be used alone, or in combination with these or other materials (as practicable).

Disposed within the thermally conductive composition is a dispersion of thermal fillers. The thermal fillers may be provided as nanomaterials and/or micromaterials.

Generally, the thermal fillers exhibit some shape or form, and therefore have at least one dimensional aspect (e.g., thin flakes having a major surface and on minor dimension or elongated elements having one major dimension and two transverse minor dimensions). The thermal fillers may be selected for dispersion and exhibit good to excellent thermal conductivity. Some examples of nanomaterials include, without limitation, such as forms of carbon nanotubes (including single-wall carbon nanotubes (SWCNT) and multi-wall carbon nanotubes (MWCNT)) as well as nanohorns, nano-onions, carbon black, fullerene, graphene, oxidized graphene, and various treated forms of the foregoing. In some embodiments, the nanomaterials further include metal nano-particles, metal oxide nano-particles, and/or at least one form of thermally conductive polymer. The thermal fillers may be provided as micromaterials and include, without limitation, graphite, boron nitride, boron nitride flakes, boron nitride nanoscrolls, aluminum nitride, aluminum nitride whiskers, carbon nanotubes, metal particles, metal oxide particles and/or at least one form of thermally conductive polymer.

As used herein, the term “micromaterials” refers to dimensional thermal filler materials that exhibit one or more dimension in the range of about 0.1 microns up to about 200 microns (e.g., microscale particles or flakes). Generally, the term “nanomaterials” refers to dimensional thermal filler materials that exhibit one or more dimensions in the range of about a few nanometers up to about 100 nanometers (0.1 microns) (e.g., nanotubes, nanorods, nanoparticles, nanoshells, nanohorns, and nanoscopic flakes such as graphene flakes).

Given the diminutive nature of the thermal fillers, in some embodiments, it is not possible to control orientation when mixing them into the thermally conductive composition. Accordingly, dispersion of the thermal fillers results in randomly oriented dimensional material disposed within the volume of the thermally conductive composition.

As the thermal fillers are randomly oriented within the thermally conductive composition, advantageous properties of directional thermal conductivity are absent. More specifically, without a directional arrangement, the isotropic thermal conductivity preference of the thermal fillers causes heat to be conducted away in random directions. The potential of the thermal fillers may be taken advantage of, however, when rearranging the dimensional thermal fillers in an anisotropic orientation to form an oriented material.

Exemplary techniques for providing oriented dimensional material include hydraulic pressing or extrusion. In some embodiments, hydraulic pressing begins with a volume of thermal conductive composition having a dispersion of randomly oriented dimensional material. The volume of material is pressed or extruded into a substantially planar form. In some embodiments, the substantially planar form is then folded onto itself, effectively being reshaped, e.g., into a ball or cubic volume. The volume of material is then again pressed into a substantially planar form. Generally, through repeated pressing and folding, the filler materials disposed in random orientation are encouraged into a planar orientation, e.g., as shown above in the layers in reference to FIGS. 8A and 8B.

In order to encourage migration of the filler materials into the desired orientation, the mixture of the thermally conductive composition with the dispersion of randomly oriented dimensional material may be heated, e.g., during a pressing or extrusion process as described above. Generally, heating of the mixture of the thermally conductive composition with the dispersion of randomly oriented dimensional material decreases the viscosity of the thermally conductive composition 1, thereby encouraging migration of the randomly oriented dimensional material into the desired orientation.

As shown in FIG. 8A by the directional arrows, when the dimensional materials are provided in a directional arrangement, the anisotropic thermal conductivity preference of the nanomaterials generally causes heat to be conducted away in [symbol] the X-Y plane. This property is taken advantage of to provide for thermal pad disclosed herein.

The oriented material may be segmented and placed into a stack 940. Once in the stack 940, the oriented thermal interface material (TIM) 900 may be further segmented. For example, the stack 940 may be cut along an imaginary plane, denoted as the A-plane, which is in the X-Z plane. The result is depicted in FIG. 8B.

FIG. 8B is an illustration of the final steps in a method of fabrication of a thermal interface pad according to various embodiments. As shown in FIG. 8B, an oriented pad 1050 includes a portion of the stack 940. Generally, the oriented pad 1050 is fabricated to dimensions suited for use in the heat management system 100 illustrated in FIG. 1. The resulting vectors substantially convey heat from the heat source 150 through the X-Y plane. While some of the thermal fillers will convey heat substantially in the X direction, it is expected that a substantially equivalent portion of the nanomaterials will convey heat substantially in the Y direction. Stated another way, while the anisotropic thermal conductivity of the thermal fillers causes a substantial portion of the heat to be conveyed through the X-Y plane, conveyance of heat in the Z direction is limited (for the same reason). Thus, there is limited recirculation of heat within the oriented pad 1050.

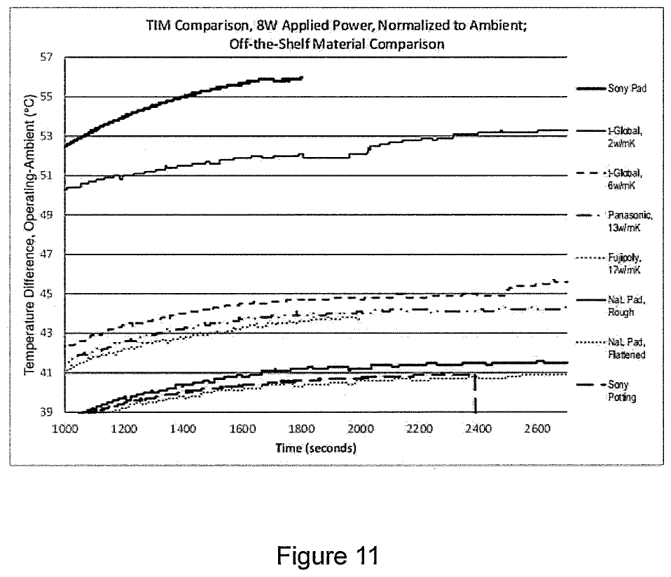

Performance of the thermal conductivity of the oriented pad 1050 was evaluated in a series of tests using a standardized test bench. Testing included comparison to competitive products. When placed in the test bench, each product experienced some compression. The compression exhibited is set forth in Table 1 below. In the data table below, “NaL Pad” refers to the oriented pad 1050. Test data for evaluation of thermal conductivity is presented in FIG. 11.

TABLE 1
Compression of comparative products

| TIM | Thickness (mm) | | Change |
|---|---|---|---|
| Description | Before | After | (%) |
| t-Global, 2 w/mK | 1.94 | 1.87 | −3.61 |
| t-Global, 6 w/mK | 2.03 | 2.025 | −0.25 |
| Panasonic, 13 w/mK | 2.02 | 2 | −0.99 |
| Fujipoly, 17 w/mK | 1.5 | 1.475 | −1.67 |
| NaL Pad, Rough | 1.755 | 1.69 | −3.70 |
| NaL Pad, Flat | 1.36 | 1.35 | −0.74 |

FIG. 11 is a graph depicting thermal performance for the oriented pad disclosed herein in comparison to competitive products. As shown in FIG. 11, the resulting oriented pad 1050 outperforms all competing pad products tested. The data shows that thermal conductivity performance of the oriented pad 1050 is substantially equivalent to thermal performance of potting material (i.e., jacketing of the heat source 150 with potting material).

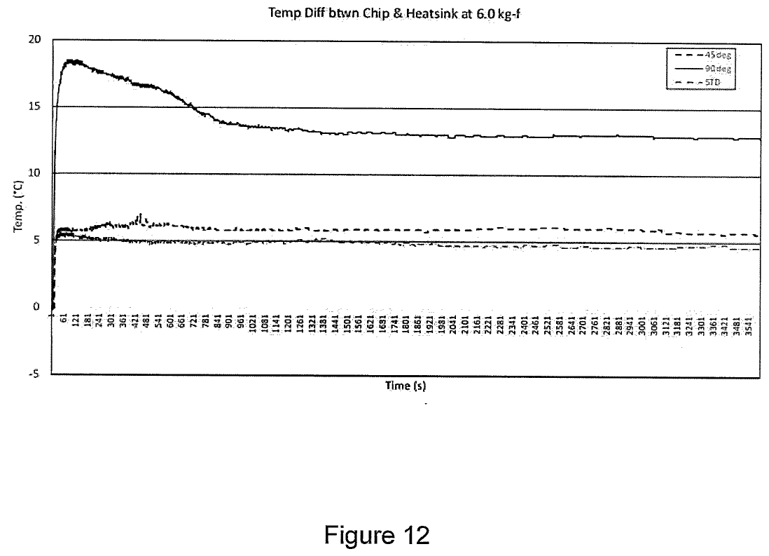

FIG. 12 is graph showing comparative performance of embodiments of thermal interface materials. Referring to FIG. 12, a comparison showing the effects realized from orientation of the dimensional thermal materials is shown. In the heat management system 100 used to generate the data shown, the heat spreader 170 was omitted. Three samples of thermal interface material 110 were tested. The first sample included a standard (STD) with substantially vertically oriented thermal filler materials. A difference in temperature between the heat source 150 and the heat sink 120 reached equilibrium quickly and maintained at about 5° C. The second sample of thermal interface material 110 (45 deg) was fabricated using a slicing technique described herein, with slicing occurring at an angle of about 45 degrees. The third sample of thermal interface material 110 contained thermal filler materials that were oriented substantially orthogonally (90 deg) to the desired direction of heat flux.

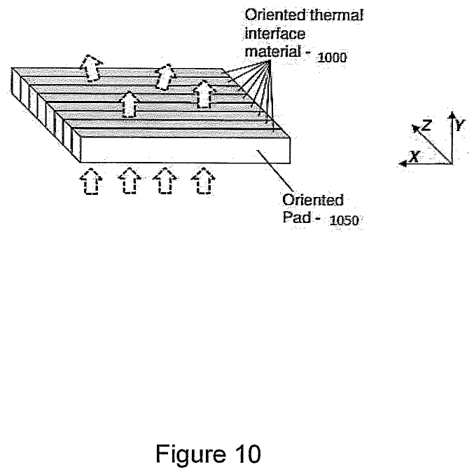

Exhibiting a smaller temperature difference between the heat source 150 and the heat sink 120 indicates lower thermal resistivity. Thus, since the first sample has the smallest temperature difference, it is clear that orienting the particles such that heat is transferred through the X-Y plane (as defined in FIG. 10) improves the thermal conductivity of the thermal interface material 110.

Having introduced aspects of thermal interface materials, some further aspects and examples are provided.

The thermal interface materials may be formed as a soft material. Generally, the thermal interface material is self-healing during fabrication (the slice-and-stack procedure).

Generally, the thermal interface material is useful in applications requiring gap filling. That it, the thermal interface materials provide for superior conformity to irregular surfaces.

In some embodiments, the thermal interface materials include a flexible polymer sheet material with thickness options from about 0.25 mm to about 5 mm, and a thermal conductivity of up to about 60 W/mK or more. Current high-performance TIM sheets tend to be around 5 W/mK. The resulting four-fold increase in performance is an enabling technology for applications using high power. Virtually any powered system could take advantage of a high performance TIM.

Applications for thermal interface materials include, without limitation: power supplies, automotive electronics, motor controls, power semiconductors, heat sink interfaces, processing systems and other electronic devices such as computers, amplifiers, video processing equipment, control systems and many others.

In some embodiments, the resulting product exhibits thermal conductivity that is at least 60 W/mK. The product may be provided in a sheet, in some embodiments, in sheets sized roughly the size of standard printer paper. The product may have a thickness of between about 0.25 mm to 5 mm and may be lesser or greater in thickness. The product may be useful in temperatures ranging between −60° C. to 250° C. (or any subrange thereof, e.g.,−40° C. to 150° C.) and may be useful in temperature ranges lesser or greater. Generally, the product is non-outgassing and does not exhibit creep with thermal cycling. Generally, the product is pliable and conforming to surrounding components.

Generally, the product is reworkable and may be use in existing/common manufacturing processes.

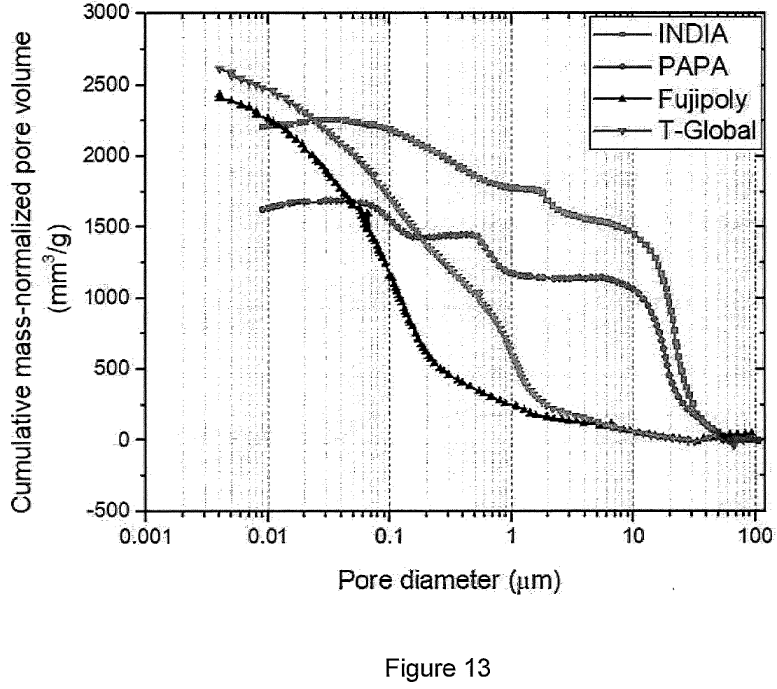

FIG. 13 is graph showing comparative performance of embodiments of thermal interface materials.

As illustrated in FIG. 13, in the range of pore diameters of 1 μm to 100 μm the top two plots are of TIMs according to various embodiments, and the bottom two plots are of competitive off-the-shelf TIMs. Referring to FIG. 13, the competitive off-the-shelf TIMs steeply decline in cumulative mas-normalized pore volume as the pore size is between approximately 0.05 μm to 1 μm. In contrast, the TIMs according to various embodiments maintain a relatively high cumulative mas-normalized pore volume as the pore size is between approximately 0.05 μm to 1 μm, and indeed until the pore size approaches approximately 11 μm. According to various embodiments, the TIM has a cumulative mass normalized pore volume greater than (or equal to) 1000 mm³/g at a pore size of 1 μm. In some embodiments, the TIM has a cumulative mass normalized pore volume greater than (or equal to) 1500 mm³/g at a pore size of 1 μm. In some embodiments, the TIM has a cumulative mass normalized pore volume greater than 2000 mm³/g at a pore size of 0.1 μm. In some embodiments, the TIM has a cumulative mass normalized pore volume greater than 2250 mm³/g at a pore size of 0.1 μm. In some embodiments, the TIM has a cumulative mass normalized pore volume greater than (or equal to) 250 mm³/g at a pore size of 10 μm. In some embodiments, the TIM has a cumulative mass normalized pore volume greater (or equal to) than 500 mm³/g at a pore size of 10 μm.

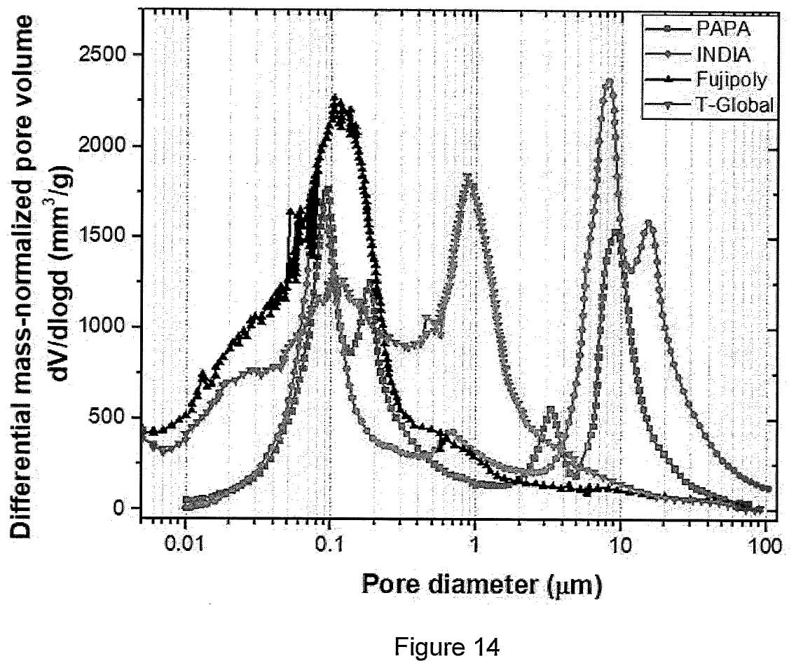

FIG. 14 is graph showing comparative performance of embodiments of thermal interface materials.

As illustrated in FIG. 14, in the range of pore diameters of 10 μm to 100 μm the top two plots are of TIMs according to various embodiments, and the bottom two plots are of competitive off-the-shelf TIMs. Referring to FIG. 14, the competitive off-the-shelf TIMs steeply have relatively low values of differential mass-normalized pore volume relative to TIMs according to various embodiments. For example, as illustrated in FIG. 14, the TIMs according to the related art have a differential mass normalized pore volume of less than about 250 mm³/g at a pore diameter of 10 μm. In contrast, the TIMs according to various embodiments maintain a relatively high differential mass normalized pore volume as the pore size is between approximately 10 μm to 15 μm. In some embodiments, the TIM has a differential mass normalized pore volume greater than 250 mm³/g at a pore size of 10 μm. In some embodiments, the TIM has a differential mass normalized pore volume greater than 500 mm³/g at a pore size of 10 μm. In some embodiments, the TIM has a differential mass normalized pore volume greater than 1000 mm³/g at a pore size of 10 μm. In some embodiments, the TIM has a differential mass normalized pore volume greater than (or approximately equal to) 1500 mm³/g at a pore size of 10 μm. n some embodiments, the TIM has a differential mass normalized pore volume greater than (or approximately equal to) 1500 mm³/g at a pore size of 2250 μm. In some embodiments, the TIM has a differential mass normalized pore volume greater than 2250 mm³/g at a pore size of 0.1 μm. In some embodiments, the TIM has a differential mass normalized pore volume less than (or equal to) 250 mm³/g at a pore size of 0.01 μm. In some embodiments, the TIM has a differential mass normalized pore volume greater (or equal to) than 100 mm³/g at a pore size of 0.01 μm.

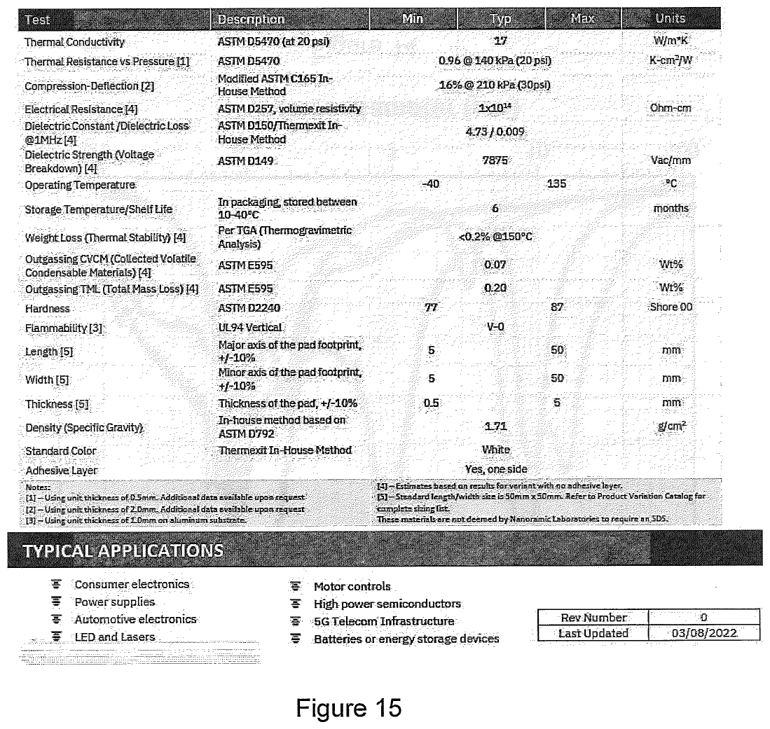

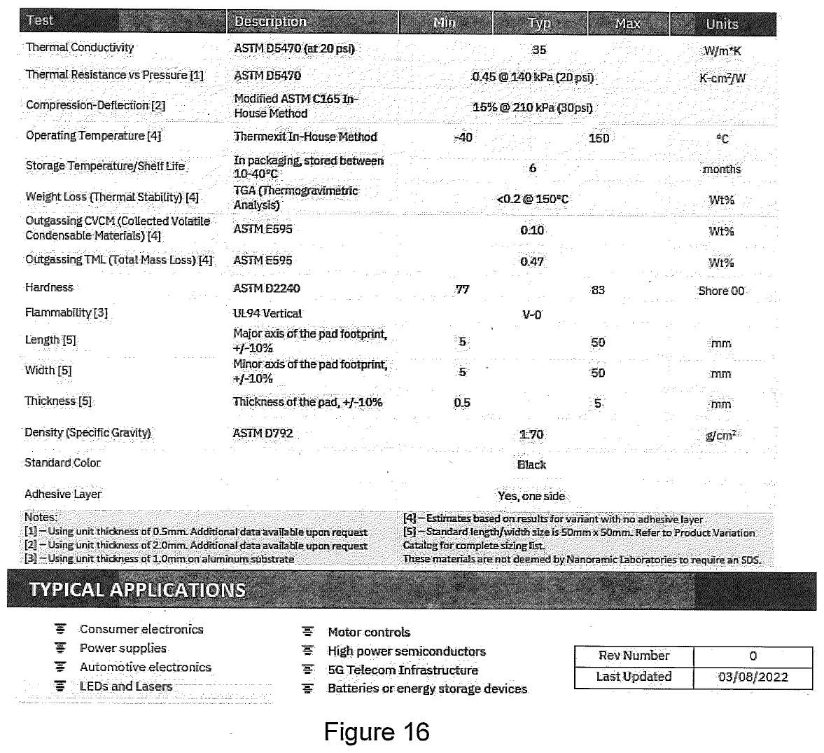

FIG. 15 is a chart showing characteristics of thermal interface materials according to various embodiments. FIG. 16 is a chart showing characteristics of thermal interface materials according to various embodiments.

Various other components may be included and called upon for providing for aspects of the teachings herein. For example, additional materials, combinations of materials and/or omission of materials may be used to provide for added embodiments that are within the scope of the teachings herein.

A variety of modifications of the teachings herein may be realized. Generally, modifications may be designed according to the needs of a user, designer, manufacturer or other similarly interested party. The modifications may be intended to meet a particular standard of performance considered important by that party.

The appended claims or claim elements should not be construed to invoke 35 U.S.C. § 112(f) unless the words “means for” or “step for” are explicitly used in the particular claim.

When introducing elements of the present invention or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements. As used herein, the term “exemplary” is not intended to imply a superlative example. Rather, “exemplary” refers to an embodiment that is one of many possible embodiments.

While the invention has been described with reference to exemplary embodiments, it will be understood by those skilled in the art that various changes may be made and equivalents may be substituted for elements thereof without departing from the scope of the invention. In addition, many modifications will be appreciated by those skilled in the art to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A thermal interface material, comprising:
a bulk layer, wherein:
the bulk layer comprises a first acrylic rubber, plasticizer particles, and first filler particles; and
the first filler particles are substantially aligned in a first direction;
and at least one adhesive layer, comprising a first adhesive layer,
wherein: the first adhesive layer is disposed on a first side of the bulk material; the first adhesive layer has a greater tackiness than the bulk material; the first adhesive layer comprises a second acrylic rubber;
the first direction is perpendicular to a first surface of the first side on which the first adhesive layer is disposed.

2. The thermal interface material of claim 1, wherein the first adhesive layer further comprises second filler particles.

3. The thermal interface material of claim 2, wherein the second filler particles comprise graphite.

4. The thermal interface material of claim 2, wherein the second filler particles comprises boron nitride.

5. The thermal interface material of claim 1, wherein a concentration of the second acrylic rubber in the first adhesive layer is greater than a concentration of the first acrylic rubber in the bulk layer.

6. The thermal interface material of claim 1, wherein a concentration of the first acrylic rubber comprised in the bulk layer is higher at a mid-point of the bulk material between the first side of the bulk material and a second side of the bulk material, the second side being on a side opposing the first acrylic rubber.

7. The thermal interface material of claim 1, wherein:
the bulk material comprises a second side that is opposite to the first side;
a middle cross section of the bulk material corresponding to a having a thickness equal to 50% of a thickness between the first side and the second side has a first average concentration of the first acrylic rubber;
an end cross section of the bulk material corresponding to a section of the bulk material at one of the first side or the second side of the bulk material having a thickness equal to 50% of a thickness between the first side and the second side has a second average concentration of the first acrylic rubber; and
the first average concentration and the second average concentration are different.

8. The thermal interface material of claim 7, wherein the middle cross section of the bulk material is measured such that a mid-point of middle of the cross section in the direction between the first side and the second side corresponds to a mid-point of the bulk material in the direction between the first side and the second side.

9. The thermal interface material of claim 7, wherein the first average concentration is higher than the second average concentration.

10. The thermal interface material of claim 1, wherein the first filler particles comprise graphite.

11. The thermal interface material of claim 1, wherein the first filler particles comprise boron nitride.

12. The thermal interface material of claim 1, wherein the plasticizer particles comprise a polyester.

13. The thermal interface material of claim 1, wherein the plasticizer particles have a relatively high molecular weight.

14. The thermal interface material of claim 1, wherein the plasticizer particles have a molecular weight of at least 4,000.

15. The thermal interface material of claim 1, wherein the plasticizer particles have a molecular weight of at least 10,000.

16. The thermal interface material of claim 1, wherein the first acrylic rubber is a self healing material.

17. The thermal interface material of claim 1, wherein the plasticizer particles have an average viscosity of 850 at 80° C.

18. The thermal interface material of claim 1, wherein the plasticizer particles have a viscosity of between 875 and 1025 at 80° C.

19. The thermal interface material of claim 1, wherein the plasticizer particles have a viscosity of between 900 and 1000 at 80° C.

20. The thermal interface material of claim 1, wherein the plasticizer particles have an average viscosity of 930 at 25° C.

21. The thermal interface material of claim 1, wherein the plasticizer particles have a viscosity of between 825 and 1025 at 25° C.

22. The thermal interface material of claim 1, wherein the plasticizer particles have a viscosity of between 850 and 1000 at 25° C.

23. The thermal interface material of claim 1, wherein the plasticizer particles comprise a first set of plasticizer particles and a second set of plasticizer particles, and the first set of plasticizer particles and the second set of plasticizer particles are different.

24. The thermal interface material of claim 23, wherein the first set of plasticizer particles have a viscosity of between 900 and 1000 at 80° C., and the second set of plasticizer particles have a viscosity of between 850 and 1000 at 25° C.

25. The thermal interface material of claim 23, wherein the first set of plasticizer particles have a viscosity of between 875 and 1025 at 80° C., and the second set of plasticizer particles have a viscosity of between 825 and 1025 at 25° C.

26. The thermal interface material of claim 1, wherein the bulk layer comprises one or more channels of air that extend along the first direction.

27. The thermal interface material of claim 1, wherein the bulk layer comprises one or more channels of air that are substantially parallel to a direction in which the first filler particles are aligned.

28. The thermal interface material of claim 1, wherein the bulk layer comprises one or more channels of air that are substantially parallel to first direction.

29. The thermal interface material of claim 1, wherein the bulk layer comprises a set of gas pockets, and the gas bubbles are aligned substantially perpendicular to a direction in which the first filler particles are aligned.

30. The thermal interface material of claim 29, wherein the gas pockets correspond to air pockets.

31. The thermal interface material of claim 1, wherein the bulk layer has a greater thermal conductivity in the first direction than in a direction perpendicular to the first direction.

32. The thermal interface material of claim 1, wherein the bulk layer has a greatest thermal conductivity in the first direction.

33. The thermal interface material of claim 1, wherein an average molecular weight of the plasticizer particles is higher than an average molecular weight of the first acrylic rubber.

34. The thermal interface material of claim 1, wherein the at least one adhesive layer comprises a second adhesive layer disposed on a side of the bulk layer that opposes the first side of the bulk layer on which the first adhesive layer is disposed.

35. The thermal interface material of claim 1, wherein the first filler particles comprise ceramic particles.

36. The thermal interface material of claim 1, wherein the first filler particles are planar.

37. The thermal interface material of claim 1, wherein the substantial alignment of the first filler particles in the first direction comprises more than 50% of the first filler particles being aligned in the first direction.

38. The thermal interface material of claim 37, wherein the first filler particles being aligned in the first direction comprises a longest side of the first filler particles being parallel to the first direction.

39. The thermal interface material of claim 1, wherein:
the substantial alignment of the first filler particles in the first direction comprises at least 75% of the first filler particles being aligned in the first direction; and
the first filler particles being aligned in the first direction comprises a longest side of the first filler particles being parallel to the first direction.

40. The thermal interface material of claim 1, wherein:
the substantial alignment of the first filler particles in the first direction comprises at least 85% of the first filler particles being aligned in the first direction; and
the first filler particles being aligned in the first direction comprises a longest side of the first filler particles being parallel to the first direction.

41. The thermal interface material of claim 1, wherein:
the substantial alignment of the first filler particles in the first direction comprises at least 90% of the first filler particles being aligned in the first direction; and
the first filler particles being aligned in the first direction comprises a longest side of the first filler particles being parallel to the first direction.

42. The thermal interface material of claim 1, wherein:
the substantial alignment of the first filler particles in the first direction comprises at least 75% of the first filler particles being aligned in the first direction; and
the first filler particles being aligned in the first direction comprises a longest side of the first filler particles being within 5 degrees of the first direction.

43. The thermal interface material of claim 1, wherein:
the substantial alignment of the first filler particles in the first direction comprises at least 85% of the first filler particles being aligned in the first direction; and
the first filler particles being aligned in the first direction comprises a longest side of the first filler particles being within 5 degrees of the first direction.

44. The thermal interface material of claim 1, wherein:
the substantial alignment of the first filler particles in the first direction comprises at least 90% of the first filler particles being aligned in the first direction; and
the first filler particles being aligned in the first direction comprises a longest side of the first filler particles being within 5 degrees of the first direction.

45. The thermal interface material of claim 1, wherein:
the substantially alignment of the first filler particles in the first direction comprises at least 90% of the first filler particles being aligned in the first direction; and
the first filler particles being aligned in the first direction comprises a longest side of the first filler particles being within 5 degrees of the first direction.

46. The thermal interface material of claim 1, wherein first filler particles comprises a first subset of first filler particles and a second subset of the first filler particles.

47. The thermal interface material of claim 46, wherein:
an average size of the first subset of first filler particles is larger than an average size of the second subset of the first filler particles.

48. The thermal interface material of claim 47, wherein a thermal conductivity of the first subset of first filler particles if more uniform than a thermal conductivity of the second subset of first filler particles.

49. The thermal interface material of claim 1, wherein the bulk layer is 80% first filler particles by weight.

50. The thermal interface material of claim 1, wherein a first tensile strength of the thermal interface material along the first direction is different from a second tensile strength of the thermal interface material along a direction that is perpendicular to the first direction.

51. The thermal interface material of claim 1, wherein a tensile strength of the thermal interface material along the first direction is less than a tensile strength of the thermal interface material along a direction that is perpendicular to the first direction.

52. The thermal interface material of claim 1, wherein:
a first tensile strength of the thermal interface material along the first direction is different from a second tensile strength of the thermal interface material along a direction that is perpendicular to the first direction; and
a ratio of the second tensile strength to the first tensile strength is at least 1.5 to 1.

53. The thermal interface material of claim 1, wherein:
a first tensile strength of the thermal interface material along the first direction is different from a second tensile strength of the thermal interface material along a direction that is perpendicular to the first direction; and
a ratio of the second tensile strength to the first tensile strength is at least 2 to 1.

54. The thermal interface material of claim 1, wherein:
a first tensile strength of the thermal interface material along the first direction is different from a second tensile strength of the thermal interface material along a direction that is perpendicular to the first direction; and
a ratio of the second tensile strength to the first tensile strength is at least 2.5 to 1.

55. The thermal interface material of claim 1, wherein:
a first tensile strength of the thermal interface material along the first direction is different from a second tensile strength of the thermal interface material along a direction that is perpendicular to the first direction; and
a ratio of the second tensile strength to the first tensile strength is at least 3 to 1.

56. The thermal interface material of claim 1, wherein the first adhesive layer further comprises second filler particles.
